(19) United States
(12) Patent Application Publication
(10) Pub. No.: US 2013/0168873 A1
(43) Pub. Date: Jul. 4, 2013

(54) POWER SEMICONDUCTOR DEVICE AND MANUFACTURING METHOD THEREOF

(71) Applicant: SAMSUNG ELECTRONICS CO., LTD., Suwon-si (KR)

(72) Inventors: Heon Bok LEE, Suwon-si (KR); Ki Se KIM, Suwon-si (KR)

(73) Assignee: SAMSUNG ELECTRONICS CO., LTD., Suwon-si (KR)

(21) Appl. No.: 13/729,218

(22) Filed: Dec. 28, 2012

(30) Foreign Application Priority Data
Dec. 29, 2011 (KR) 10-2011-0146206

(51) Int. Cl. H01L 23/48; H01L 21/768

(52) U.S. Cl. CPC H01L 23/481; H01L 21/76897
USPC 257/774; 438/652

(57) ABSTRACT

A power semiconductor device and a manufacturing method thereof, the power semiconductor device including a plurality of first electrodes and a plurality of second electrodes, a plurality of first via electrodes on a first insulating layer and contacting the plurality of first electrodes, a plurality of second via electrodes on the first insulating layer and contacting the plurality of second electrodes, a first electrode pad contacting the plurality of first via electrodes, a second electrode pad contacting the plurality of second via electrodes, a plurality of third via electrodes on a second insulating layer and contacting the first electrode pad, a plurality of fourth via electrodes on the second insulating layer and contacting the second electrode pad, a third electrode pad contacting the plurality of third via electrodes, and a fourth electrode pad contacting the plurality of fourth via electrodes.

### CROSS-REFERENCE TO RELATED APPLICATION

The present application claims priority under 35 U.S.C. §119 to Korean Patent Application No. 10-2011-1046206, filed on Dec. 29, 2011, in the Korean Intellectual Property Office, and entitled: “Power Semiconductor Device and Manufacturing Method Thereof,” which is incorporated by reference herein in its entirety.

### BACKGROUND

1. Field of the Invention

Embodiments relate to a power semiconductor device and a manufacturing method thereof.

2. Description of the Related Art

A power semiconductor device may be made of silicon. Due to a physical limit of silicon, a power semiconductor device using a gallium nitride (GaN)-based material may be used. The GaN-based material has an energy gap that is almost 3 times greater than an energy gap of silicon. Also, the GaN-based material may have high thermal and chemical stability, high electron saturation velocity, and the like. Thus, the GaN-based material may be applicable not only to an optical device but also to an electronic device for high frequency and high output.

### SUMMARY

Embodiments are directed to a power semiconductor device and a manufacturing method thereof.

The embodiments may be realized by providing a power semiconductor device including a plurality of first electrodes and a plurality of second electrodes alternately arranged on an epi structure; a first insulating layer on the epi structure, the first insulating layer including at least one first region alternately arranged with at least one second region; a plurality of first via electrodes on the first region of the first insulating layer, the plurality of first via electrodes contacting the plurality of first electrodes; a plurality of second via electrodes on the second region of the first insulating layer, the plurality of second via electrodes contacting the plurality of second electrodes; at least one first electrode pad on the first region, the at least one first electrode pad contacting the plurality of first via electrodes; at least one second electrode pad on the second region, the at least one second electrode pad contacting the plurality of second via electrodes; a second insulating layer on the at least one first electrode pad and the at least one second electrode pad, the second insulating layer including a third region and a fourth region; a plurality of third via electrodes on the third region of the second insulating layer, the plurality of third via electrodes contacting the at least one first electrode pad; a plurality of fourth via electrodes on the fourth region of the second insulating layer, the plurality of fourth via electrodes contacting the at least one second electrode pad; at least one third electrode pad on the third region, the at least one third electrode pad contacting the plurality of third via electrodes; and at least one fourth electrode pad disposed on the fourth region, the at least one third electrode pad contacting the plurality of fourth via electrodes.

The plurality of first via electrodes and the plurality of second via electrodes may each have a first size, and the plurality of third via electrodes and the plurality of fourth via electrodes may each have a second size, the second size larger than the first size.

The plurality of first via electrodes and the plurality of second via electrodes may each have a first size, the plurality of third via electrodes may each have a second size, the second size being larger than the first size, and the plurality of fourth via electrodes may each have a third size, the third size being larger than the first size and being different from the second size.

The plurality of first electrodes may each have a tapered structure that widens from one side to an opposite side of the epi structure.

The plurality of second electrodes may each have a tapered structure that widens from the opposite side to the one side of the epi structure.

The plurality of second via electrodes may each have a trapezoidal shape that widens toward the opposite side within the second region and corresponds to the tapered structure of the plurality of second electrodes.

The plurality of first via electrodes may each have a trapezoidal shape that widens toward the opposite side within the first region and corresponds to the tapered structure of the plurality of first electrodes.

The first region and the second region may be arranged symmetrically to each other with respect to a first straight line passing through a center of the epi structure.

The third region and the fourth region may be arranged symmetrically to each other with respect to a second straight line passing through the center of the epi structure, the second straight line being orthogonal to the first straight line.

The first region and the second region may each have a major axis that extends in a direction crossing a major axis of the plurality of first electrodes and the plurality of second electrodes in the first insulating layer.

The third region and the fourth region may each have a major axis that extends in a direction crossing a major axis of the at least one first electrode pad and the at least one second electrode pad in the second insulating layer.

The embodiments may also be realized by providing a manufacturing method for a power semiconductor device, the method including forming a plurality of first electrodes and a plurality of second electrodes such that the plurality of first electrodes and the plurality of second electrodes are alternately arranged on an epi structure; forming a first insulating layer on the epi structure such that the first insulating layer includes at least one first region alternately arranged with at least one second region; forming a plurality of first via holes in the first region of the first insulating layer such that the plurality of first electrodes are exposed; forming a plurality of second via holes in the second region of the first insulating layer such that the plurality of second electrodes are exposed; forming a plurality of first via electrodes by casting a metallic material in the plurality of first via holes; forming a plurality of second via electrodes by casting a metallic material in the plurality of second via holes; forming at least one first electrode pad in contact with the plurality of first via electrodes on the first region; forming at least one second electrode pad in contact with the plurality of second via electrodes disposed on the second region; forming a second insulating layer on the at least one first electrode pad and the at least one second electrode pad, the second insulating layer including a third region and a fourth region; forming a plurality of third via holes in a third region of the second insulating layer such that the at least one first electrode pad is exposed; forming a plurality of fourth via holes in a fourth region of the second insulating layer such that the at least one second electrode pad is exposed; forming a plurality of third via electrodes by casting a metallic material in the plurality of third via holes; forming a plurality of fourth via electrodes by casting a metallic material in the plurality of fourth via holes; forming at least one third electrode pad in contact with the plurality of third via electrodes on the third region; and forming at least one fourth electrode pad in contact with the plurality of fourth via electrodes on the fourth region.

Forming the plurality of first via holes and the plurality of second via holes may include forming the plurality of first via holes and the plurality of second via holes to each have a first size, and forming the plurality of third via holes and the plurality of fourth via holes may include forming the plurality of third via holes and the plurality of fourth via holes to each have a second size that is larger than the first size.

Forming the plurality of first via holes and the plurality of second via holes may include forming the plurality of first via holes and the plurality of second via holes to each have a first size, forming the plurality of third via holes and the plurality of fourth via holes may include forming the plurality of third via holes to each have a second size that is larger than the first size, and forming the plurality of fourth via holes to have a third size that is larger than the first size and that is different from the second size.

Forming the plurality of first electrodes and the plurality of second electrodes may include forming the plurality of first electrodes such that each of the first electrodes has a tapered structure that widens from one side to an opposite side of the epi structure, and forming the plurality of second electrodes such that each of the second electrodes has a tapered structure that widens from the opposite side to the one side of the epi structure.

Forming the plurality of first via holes and the plurality of second via holes may include forming the plurality of first via holes such that each of the first via holes has a trapezoidal shape that widens in a direction from the opposite side of the epi structure to the one side of the epi structure and that corresponds to the tapered structure of the plurality of first electrodes, and forming the plurality of second via holes such that each of the second via holes has a trapezoidal shape that widens in a direction from the one side of the epi structure to the opposite side of the epi structure and that corresponds to the tapered structure of the plurality of second electrodes.

The first region and the second region may be arranged symmetrically to each other with respect to a first straight line passing through a center of the epi structure.

The third region and the fourth region may be arranged symmetrical to each other with respect to a second straight line passing through the center of the epi structure, the second straight line being orthogonal to the first straight line.

The first region and the second region may each have a major axis that extends in a direction crossing a major axis of the plurality of first electrodes and the plurality of second electrodes in the first insulating layer.

The third region and the fourth region may each have a major axis that extends in a direction crossing a major axis of the at least one first electrode pad and the at least one second electrode pad in the second insulating layer.

### BRIEF DESCRIPTION OF THE DRAWINGS

Features will become apparent to those of skill in the art by describing in detail exemplary embodiments with reference to the attached drawings in which:

FIGS. 1 to 9 illustrate diagrams of stages in a manufacturing method of a power semiconductor device, according to an embodiment;

FIG. 10 illustrates a sectional view of the power semiconductor device shown in FIG. 9, taken along a line A-A′;

FIG. 11 illustrates a sectional view of the power semiconductor device shown in FIG. 9, taken along a line B-B′;

FIGS. 12 to 14 illustrate diagrams of stages in a manufacturing method of a power semiconductor device according to an embodiment;

FIG. 15 illustrates a sectional view of the power semiconductor device shown in FIG. 14, taken along a line C-C′;

FIG. 16 illustrates a sectional view of the power semiconductor device shown in FIG. 14, taken along a line D-D′;

FIGS. 17 through 37 illustrate diagrams of stages in a manufacturing method of a power semiconductor device according to an embodiment; and

FIG. 38 illustrates a plan view of a power semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Terms to be used below are defined based on their functions in the embodiments and may vary according to users, user's intentions, or practices. Therefore, the definitions of the terms should be determined based on the entire specification.

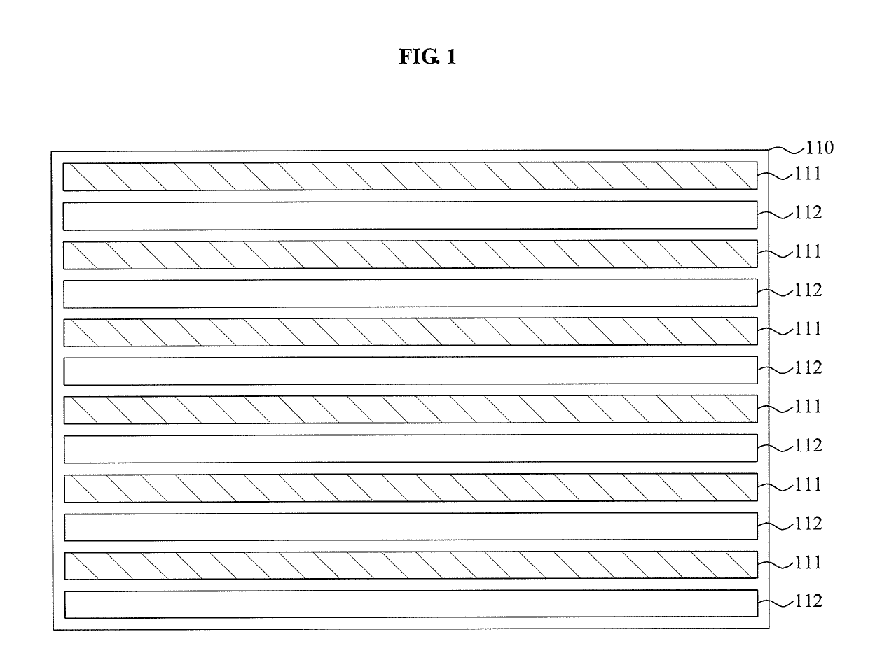

FIGS. 1 to 9 illustrate stages in a manufacturing method of a power semiconductor device, according to an embodiment. For example, FIGS. 1 to 9 show a process for realizing a multilayer electrode pad. The power semiconductor device may be, e.g., a Schottky diode, a semiconductor transistor device, or the like.

Referring to FIG. 1, first, the manufacturing method may include forming a plurality of first electrodes 111 and a plurality of second electrodes 112 on an epi structure 110.

Although not shown in detail in FIG. 1, the epi structure 110 may include at least one nitride-based semiconductor layer on a base substrate (e.g., a silicon (Si) substrate, a Si carbide (SiC) substrate, an aluminum nitride (AlN) substrate, a gallium nitride (GaN) substrate, or a sapphire substrate).

The plurality of first electrodes 111 and the plurality of second electrodes 112 may be on the epi structure 110. In an implementation, the plurality of first electrodes 111 may be anode electrodes and the plurality of second electrodes 112 may be cathode electrodes.

The plurality of first electrodes 111 and the plurality of second electrodes 112 may be alternately arranged, and may be disposed a predetermined distance apart from each other. The plurality of first electrodes 111 and the plurality of second electrodes 112 may be formed by, e.g., vapor-depositing a metallic material for forming an electrode on the epi structure 110 and performing patterning.

As shown in FIG. 1, the plurality of first electrodes 111 and the plurality of second electrodes 112 may be in a finger structure having a first length. In the state where the plurality of first electrodes 111 and the plurality of second electrodes 112 are alternately arranged, as an adjoining length, e.g., the first length, is increased, a higher current may be achieved. However, when the first length is increased, a device size may need to be increased, and resistance may be generated between the plurality of first electrodes 111 and the plurality of second electrodes 112. As a result, it may become difficult to realize an equipotential and equicurrent state and a high withstand voltage. Accordingly, embodiments will suggest a power semiconductor device capable of realizing the equipotential and equicurrent state and the high withstand voltage, by forming the multilayer electrode pad on the plurality of first electrodes 111 and the plurality of second electrodes 112.

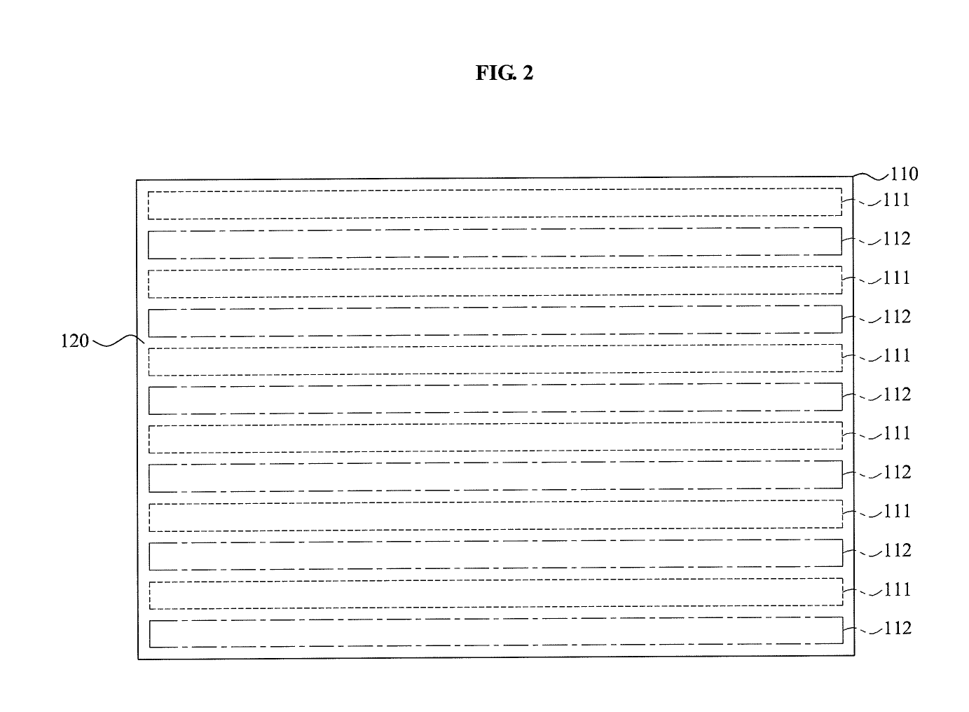

Referring to FIG. 2, the manufacturing method may include forming a first insulating layer 120 (by vapor-depositing an insulating material on the epi structure 110) to cover the plurality of first electrodes 111 and the plurality of second electrodes 112.

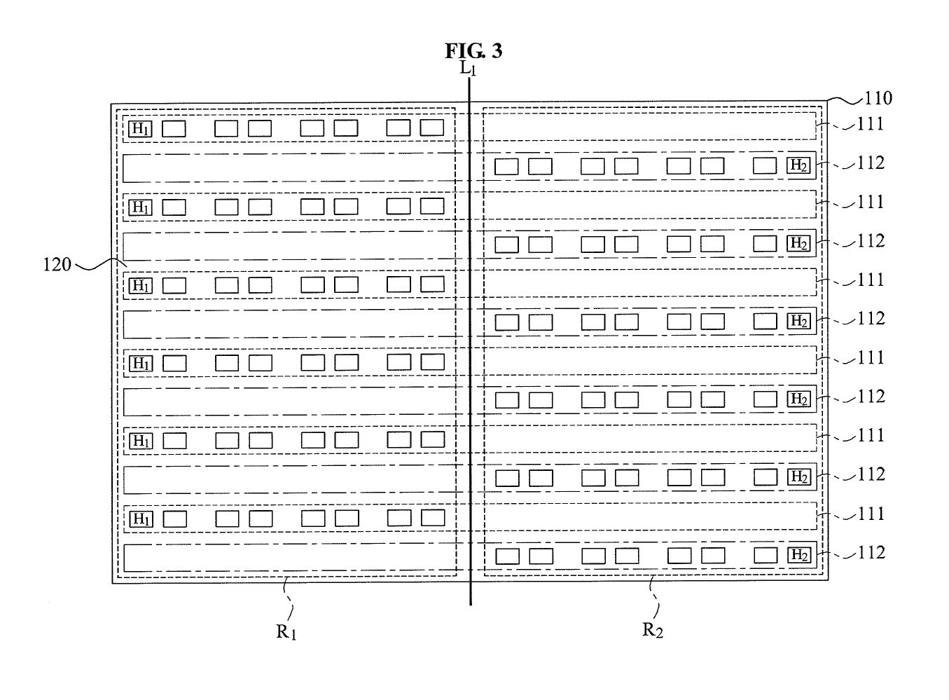

Referring to FIG. 3, the manufacturing method may include forming a plurality of first via holes H₁ and a plurality of second via holes H₂ in the first insulating layer 120.

After the first insulating layer 120 is formed, an upper portion of the first insulating layer 120 may be divided into a first region R₁ and a second region R₂, which alternate at least once. Referring to FIG. 3, the first region R₁ and the second region R₂ may be arranged symmetrically to each other with respect to a first straight line L1 that passes through a center of the epi structure 110.

The first region R₁ may be a region to form a first electrode pad. The second region R₂ may be a region in which a second electrode pad is to be formed. For example, the first region R₁ and the second region R₂ may be defined according to the regions in which the first electrode pad and the second electrode pad are to be formed. In addition, as shown in FIG. 3, the first region R₁ and the second region R₂ may alternate once or, in an implementation, at least twice.

The plurality of first via holes H₁ may be formed in the first region R₁ of the first insulating layer 120 such that the plurality of first electrodes 111 is exposed. The plurality of second via holes H₂ may be formed in the second region R₁ of the first insulating layer 120 such that the plurality of second electrodes 112 is exposed. The plurality of first via holes H₁ and the plurality of second via holes H₂ may be formed by selectively etching the first insulating layer 120.

The plurality of first via holes H₁ and the plurality of second via holes H₂ may each have a first size, e.g., a first width, a first length, a first area, or the like. The first size may include a width smaller than widths of each of the plurality of first electrodes 111 and the plurality of second electrodes 112. In addition, the plurality of first electrodes 111 and the plurality of second electrodes 112 may be provided in a square or rectangular shape.

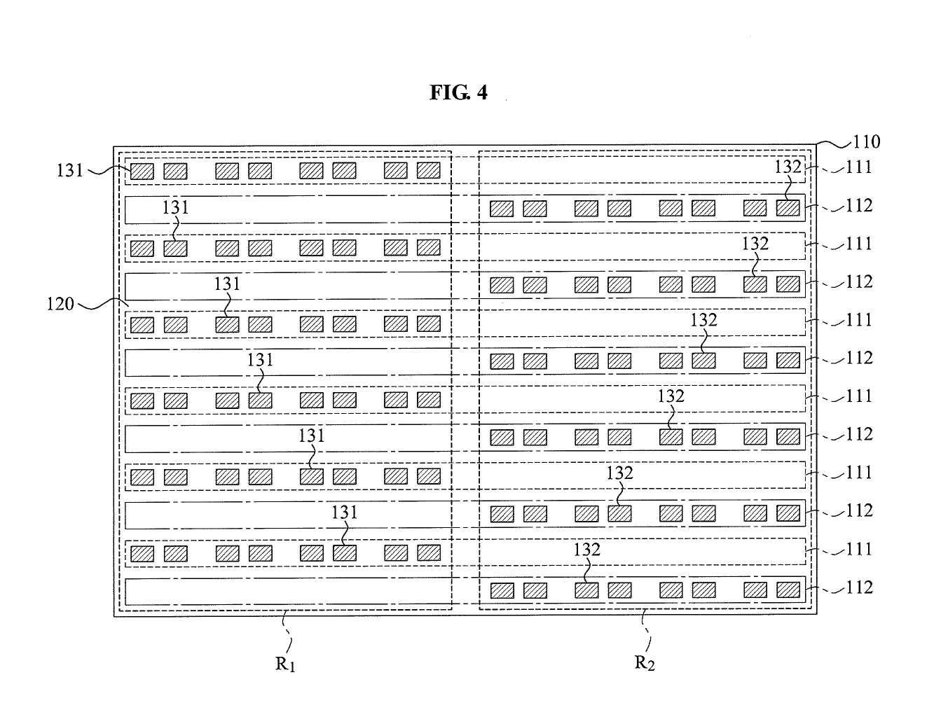

Referring to FIG. 4, the manufacturing method may include forming a plurality of first via electrodes 131 by casting a metallic material in the plurality of first via holes H₁, and forming a plurality of second via electrodes 132 by casting a metallic material in the plurality of second via holes H₂. For example, the plurality of first via electrodes 131 may be in the first region R₁ of the first insulating layer 120 and may contact the plurality of first electrodes 111. The plurality of second via electrodes 132 may be in the second region R₂ of the first insulating layer 120 and may contact the plurality of second electrodes 112.

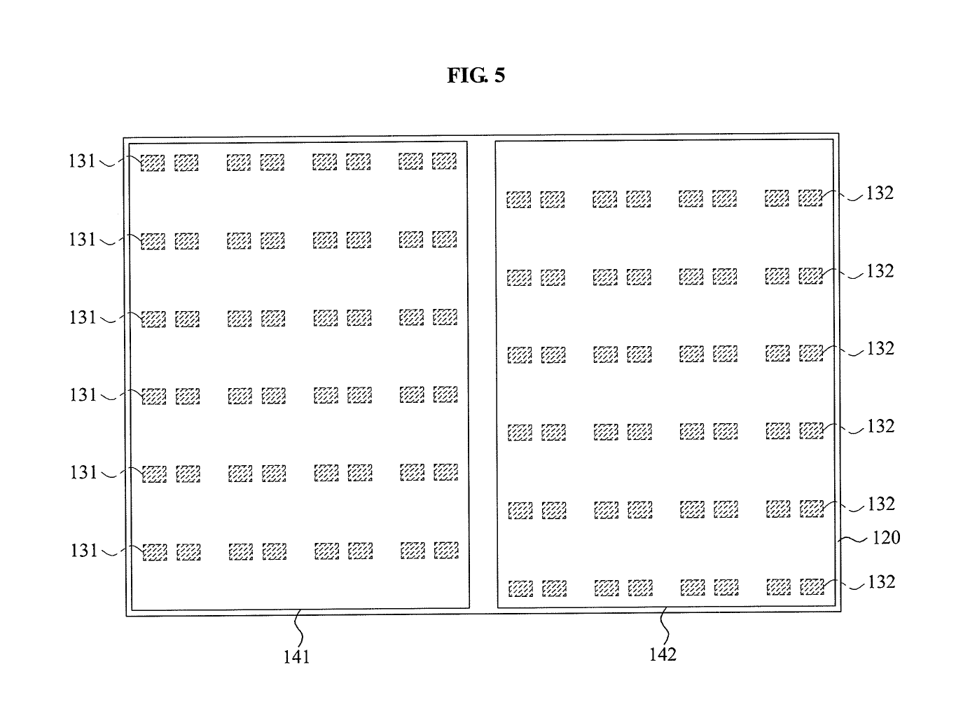

Referring to FIG. 5, the manufacturing method may include forming a first electrode pad 141 on the first region R₁ of the first insulating layer 120 and forming a second electrode pad 142 on the second region R₂ of the first insulating layer 120. As a result of such an operation, the first electrode pad 141 may contact the plurality of first via electrodes 131 exposed on the first region R₁, and the second electrode pad 142 may contact the plurality of second via electrodes 132 exposed on the second region R₂.

The plurality of first via electrodes 131 may function as a line for electrically connecting the plurality of first electrodes 111 with the first electrode pad 141. The plurality of second via electrodes 132 may function as a line for electrically connecting the plurality of second electrodes 112 with the second electrode pad 142.

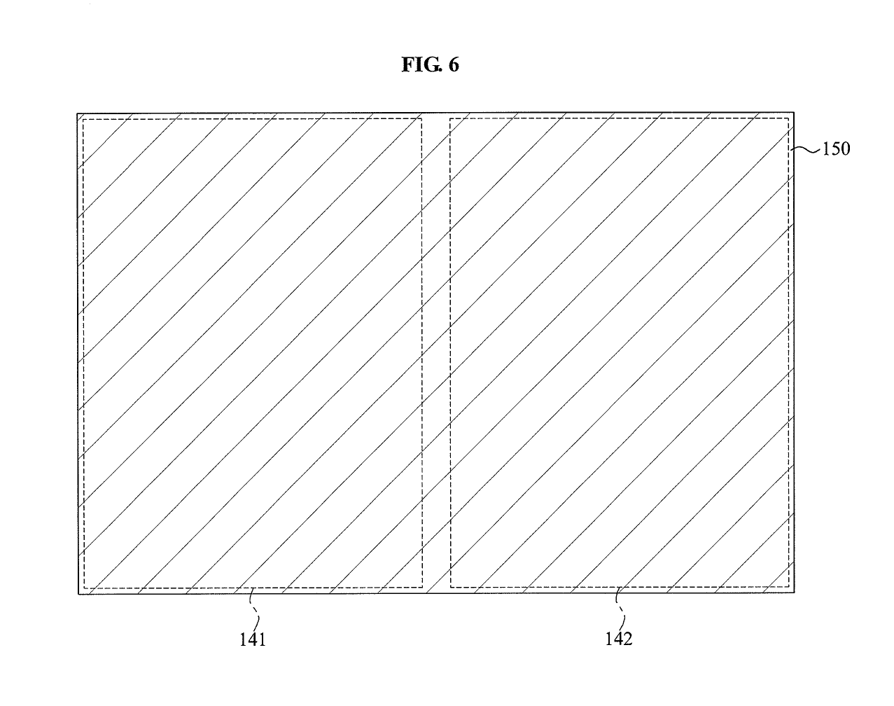

Referring to FIG. 6, the manufacturing method may include forming a second insulating layer 150 by vapor-depositing an insulating material to cover the first electrode pad 141 and the second electrode pad 142.

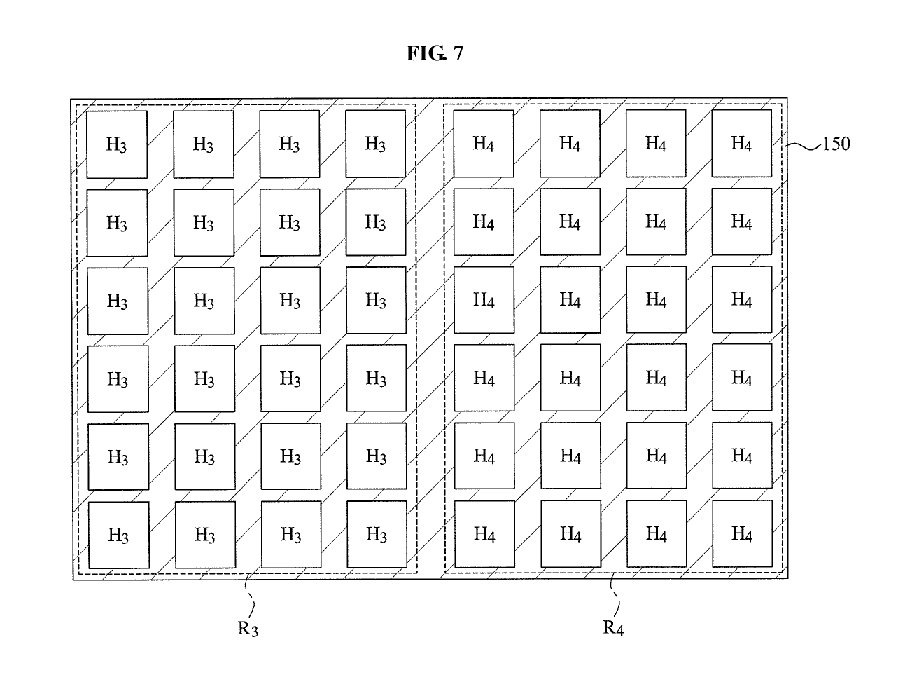

Referring to FIG. 7, the manufacturing method may include forming a plurality of third via holes H₃ and a plurality of fourth via holes H₄ in the second insulating layer 150.

For example, after the second insulating layer 150 is formed, the second insulating layer 150 may be divided into a third region R₃ and a fourth region R₄, which alternate at least once, i.e., at least one third region R₃ and at least one fourth region R₄ is present. For example, referring to FIG. 7, the third region R₃ and the fourth region R₄ may be arranged symmetrically to each other with respect to the first straight line L1 that passes through the center of the epi structure 110. For example, the third region R₃ may correspond to the first region R₁ while the fourth region R₄ may correspond to the second region R₂.

The third region R₃ may be a region in which a third electrode pad is to be formed. The fourth region R₄ may be a region in which a fourth electrode pad is to be formed. For example, the third region R₃ and the fourth region R₄ may be defined according to the regions in which the third electrode pad and the fourth electrode pad are to be formed.

The plurality of third via holes H₃ may be formed in the third region R₃ of the second insulating layer 150 such that at least a portion of the first electrode pad 141 is exposed. The plurality of fourth via holes H₄ may be formed in the fourth region R₄ of the second insulating layer 150 such that at least a portion of the second electrode pad 142 is exposed.

The plurality of third via holes H₃ and the plurality of fourth via holes H₄ may have a second size, e.g., a second width, a second length, a second area, or the like, that is larger than the first size of the plurality of first via holes H₁ and the plurality of second via holes H₂. In an implementation, the plurality of third via holes H₃ and the plurality of fourth via holes H₄ may be provided in or have a square or rectangular shape.

In an implementation, the plurality of third via holes H₃ may have a second size that is larger than the first size of the plurality of first via holes H₁ and the plurality of second via holes H₂, and the plurality of fourth via holes H₄ may have a third size, e.g., a third width, a third length, a third area, or the like, that is larger than the first size and different from the second size. For example, the third size may be larger or smaller than the second size.

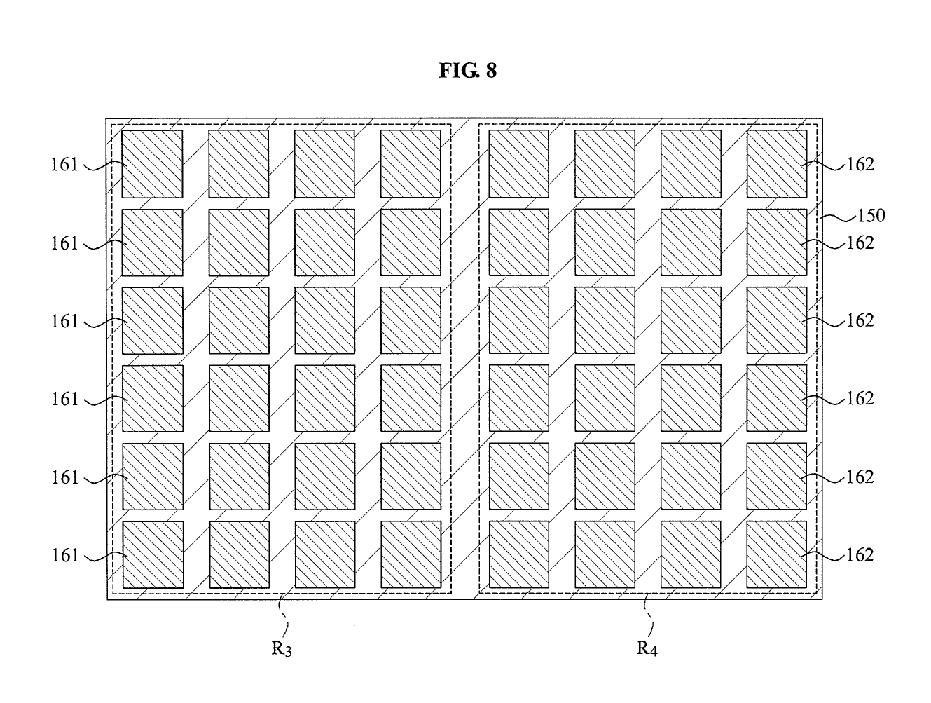

Referring to FIG. 8, the manufacturing method may include forming a plurality of third via electrodes 161 by casting a metallic material in the plurality of third via holes H₃, and forming a plurality of fourth via electrodes 162 by casting a metallic material in the plurality of fourth via holes H₄. For example, the plurality of third via electrodes 161 may be formed in the third region R₃ of the second insulating layer 150 and may contact the first electrode pad 141. The plurality of fourth via electrodes 162 may be formed in the fourth region R₄ of the second insulating layer 150 and may contact the second electrode pad 142.

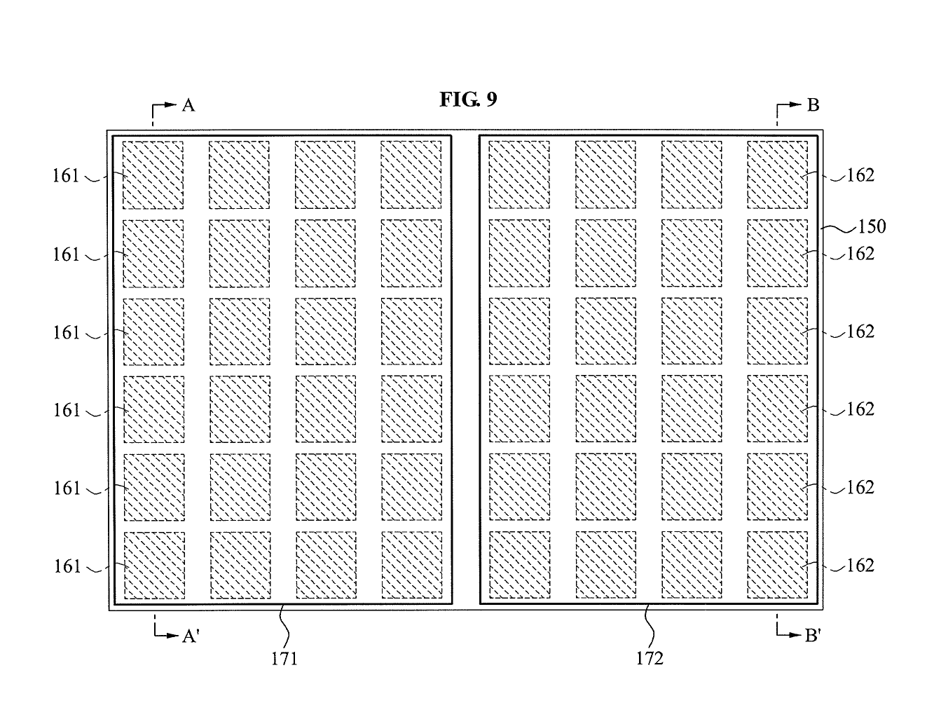

Referring to FIG. 9, the manufacturing method may include forming a third electrode pad 171 on the third region R₃ of the second insulating layer 150 and forming a fourth electrode pad 172 on the fourth region R₄ of the second insulating layer 150. As a result of such an operation, the third electrode pad 171 may contact the plurality of fourth via electrodes 161 exposed on the third region R₃, and the fourth electrode pad 172 may contact the plurality of fourth via electrodes 162 exposed on the fourth region R₄.

The plurality of third via electrodes 161 may function as a line for electrically connecting the first electrode pad 141 with the third electrode pad 171. The plurality of fourth via electrodes 162 may function as a line for electrically connecting the second electrode pad 142 with the fourth electrode pad 172.

Referring to FIG. 9, the power semiconductor device may have a multilayer structure. For example, the first electrode pad 141 and the second electrode pad 142 may be disposed on the plurality of first electrodes 111 and the plurality of second electrodes 112, respectively, and disposed on a same plane of the first insulating layer 120, e.g., may have a side facing and sharing a plane with the first insulating layer 120, thereby constructing a first-layer electrode pad.

The third electrode pad 171 and the fourth electrode pad 172 may be disposed on the first electrode pad 141 and the second electrode pad 142, respectively, and may be disposed on the same plane of the second insulating layer 150, e.g., may have a side facing and sharing a plane with the second insulating layer 150, thereby constructing a second-layer electrode pad.

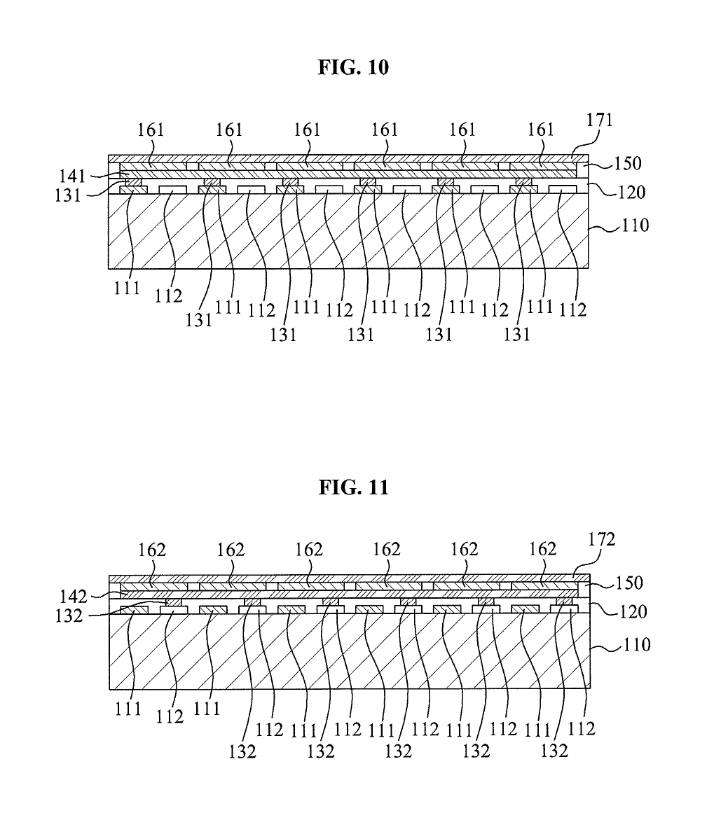

FIG. 10 illustrates a sectional view of the power semiconductor device shown in FIG. 9, taken along a line A-A′. FIG. 11 illustrates a sectional view of the power semiconductor device shown in FIG. 9, taken along a line B-B′. An electrode structure of the power semiconductor device will be described in detail with reference to FIGS. 10 and 11.

For example, FIG. 10 illustrates the third region R₃ of the power semiconductor device shown in FIG. 9, taken along the line A-A′. An electrical connection structure of the plurality of first electrodes 111, the first electrode pad 141, and the third electrode pad 171 is shown in FIG. 10.

As shown in FIG. 10, the plurality of first electrodes 111 and the plurality of second electrodes 112 may be alternately arranged on the epi structure 110. The first insulating layer 120 may be on the plurality of first electrodes 111 and the plurality of second electrodes 112. The first insulating layer 120 may include or surround the plurality of first via electrodes 131 contacting the plurality of first electrodes 111. The plurality of first via electrodes 131 may have the first size.

The first electrode pad 141 may be on the first insulating layer 120 and may contact the plurality of first via electrodes 131 exposed through the first insulating layer 120. For example, the plurality of first via electrodes 131 may function as a line for electrically connecting the plurality of first electrodes 111 and the first electrode pad 141.

The second insulating layer 150 may be on the first electrode pad 141 and may include or surround the plurality of third via electrodes 161 contacting the first electrode pad 141. The plurality of third via electrodes 161 may have the second size that is larger than the first size.

The third electrode pad 171 may be on the second insulating layer 150 and may contact the plurality of third via electrodes 161 exposed through the second insulating layer 150. For example, the plurality of third via electrodes 161 may function as a line for electrically connecting the first electrode pad 141 with the third electrode pad 171.

FIG. 11 illustrates the third region R₄ of the power semiconductor device shown in FIG. 9, taken along the line B-B′. An electrical connection structure of the plurality of second electrodes 112, the second electrode pad 142, and the fourth electrode pad 172 is shown in FIG. 11.

The plurality of first electrodes 111 and the plurality of second electrodes 112 may be alternately arranged on the epi structure 110. The first insulating layer 120 may be on the plurality of first electrodes 111 and the plurality of second electrodes 112, and may include or surround the plurality of second via electrodes 132 contacting the plurality of second electrodes 112. The plurality of second via electrodes 131 may have the first size.

The second electrode pad 142 may be on the first insulating layer 120 and may contact the plurality of second via electrodes 132 exposed through the first insulating layer 120. For example, the plurality of second via electrodes 132 may function as a line for electrically connecting the plurality of second electrodes 112 with the second electrode pad 142.

The second insulating layer 150 may be on the second electrode pad 142 and may include or surround the plurality of fourth via electrodes 162 contacting the second electrode pad 142. The plurality of fourth via electrodes 162 may have the second size that is larger than the first size, or may have the third size that is larger than the first size and different from the second size.

The fourth electrode pad 172 may be on the second insulating layer 150 and may contact the plurality of fourth via electrodes 162 exposed through the second insulating layer 150. For example, the plurality of fourth via electrodes 162 may function as a line for electrically connecting the second electrode pad 142 with the fourth electrode pad 172.

As shown in FIGS. 10 and 11, the first electrode pad 141 and the second electrode pad 142 may be on the same plane, e.g., on the first insulating layer 120, thereby constructing the first-layer electrode pad. The third electrode pad 171 and the fourth electrode pad 172 may be on the same plane, e.g., on the second insulating layer 150, thereby constructing the second-layer electrode pad.

As mentioned above, the electrode pad of the power semiconductor device may be configured to have the multilayer structure. Thus, an equipotential and equicurrent state may be achieved throughout an overall surface of the power semiconductor device, irrespective of a size of the power semiconductor device.

In addition, a resistance induced may be reduced during operation of the power semiconductor device. Also, a high current and high withstand voltage may be achieved. For example, when via electrodes are reduced in size toward an upper portion, the resistance by the current spreading may be minimized.

Furthermore, as the resistance between the plurality of first electrodes 111 and the plurality of second electrodes 112 is reduced, a size, e.g., a width, of the plurality of first electrodes 111 and the plurality of second electrodes 112 may be reduced. As a result, a degree of integration of the plurality of first electrodes 111 and the plurality of second electrodes 112 may be increased.

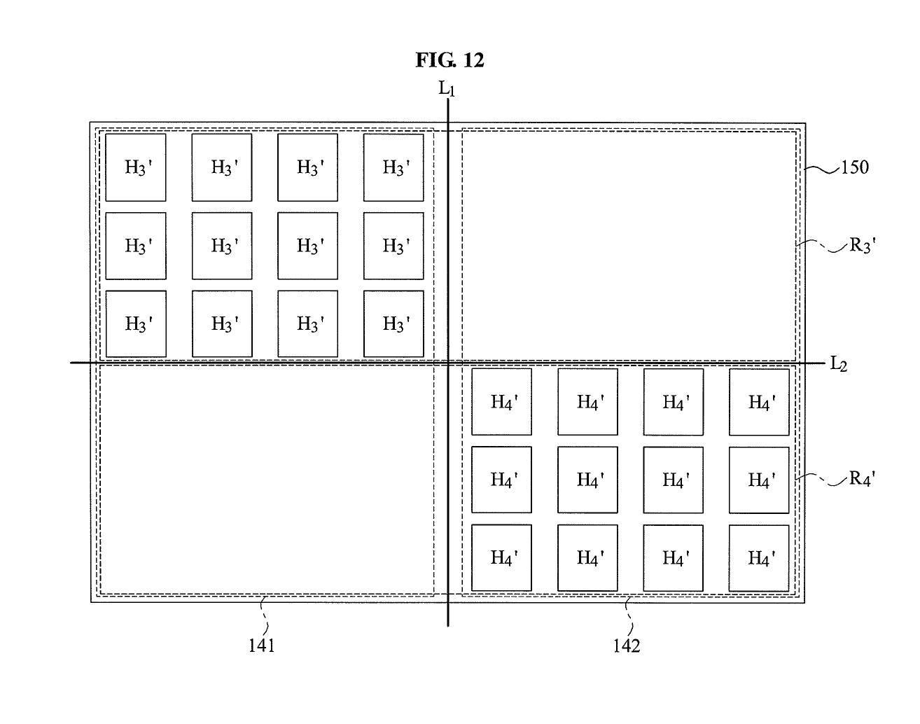

FIGS. 12 to 14 illustrate stages in a manufacturing method for a power semiconductor device according to an embodiment. The second insulating layer 150 may be formed on the epi structure 110 according to the process illustrated in FIGS. 1 to 6. However, according to the present embodiment, a third region R₃′ and a fourth region R₄′ may be defined on the second insulating layer 150 in a different manner from that illustrated in FIG. 7.

In FIG. 7, the third region R₃ is defined to correspond to the first region R₁ and the fourth region R₄ is defined to correspond to the second region R₂. However, in the present embodiment, the third region R₃′ and the fourth region R₄′ may be defined to cross the first region R₁ and the second region R₂, on the insulating layer 150.

For example, the third region R₃′ and the fourth region R₄′ may be arranged symmetrically to each other with respect to a second straight line L₂ that passes through the center of the epi structure 110 and orthogonal to the first straight line L1.

Referring to FIG. 12, the manufacturing method may include forming a plurality of third via holes H₃′ and a plurality of fourth via holes H₄′ on the second insulating layer 150. For example, the plurality of third via holes H₃′ may be formed in the third region R₃′ of the second insulating layer 150 such that at least a portion of the first electrode pad 141 is exposed. The plurality of fourth via holes H₄′ may be formed in the fourth region R₄′ of the second insulating layer 150 such that at least a portion of the second electrode pad 142 is exposed.

The plurality of third via holes H₃′ and the plurality of fourth via holes H₄′ may have a second size that larger than the first size of the plurality of first via holes H₁ and the plurality of second via holes H₂, and may be provided in or have a square or rectangular shape.

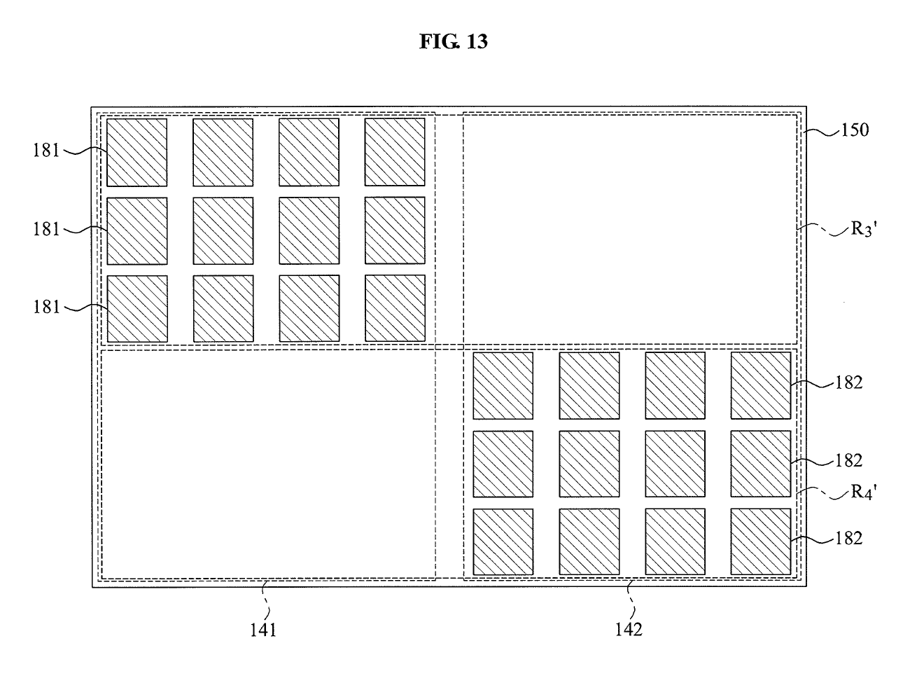

Referring to FIG. 13, the manufacturing method may include forming a plurality of third via electrodes 181 by casting a metallic material in the plurality of third via holes H₃′, and forming a plurality of fourth via electrodes 182 by casting a metallic material in the plurality of fourth via holes H₄′. The plurality of third via electrodes 181 may be in the third region R₃′ of the second insulating layer 150 and may contact the first electrode pad 141. The plurality of third via electrodes 182 may be in the fourth region R₄′ of the second insulating layer 150 and may contact the second electrode pad 142.

For example, the plurality of third via electrodes 181 may be in the third region R₃′ (crossing the first region R₁) and may contact the first electrode pad 141. The plurality of fourth via electrodes 182 may be in the fourth region R₄′ (crossing the second region R₂) and may contact the second electrode pad 142.

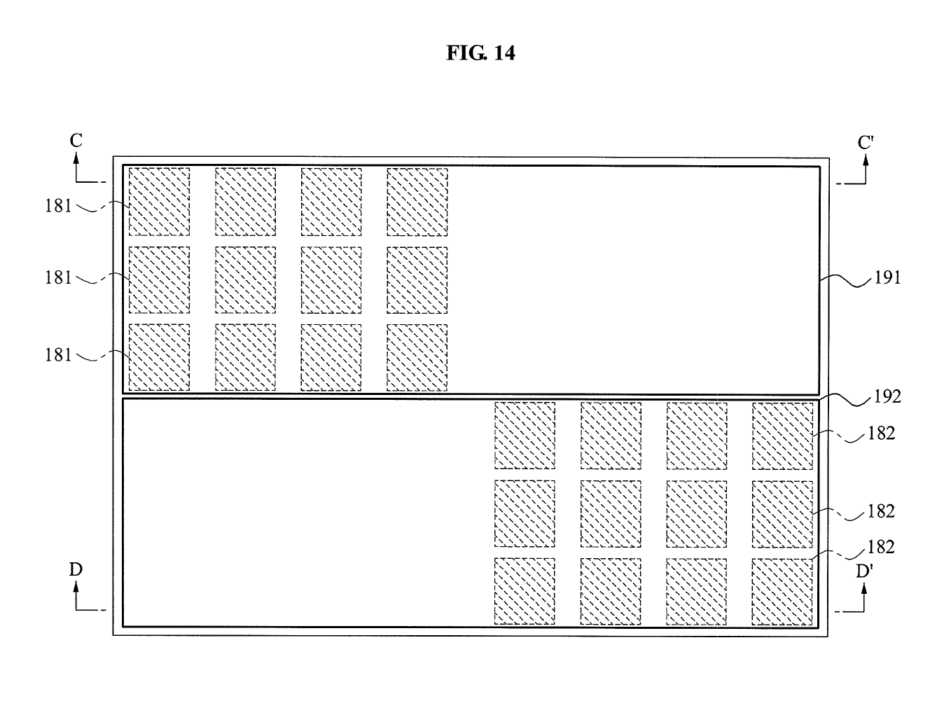

Referring to FIG. 14, the manufacturing method may include forming a third electrode pad 191 on the third region R₃′ of the second insulating layer 150, and fat ming a fourth electrode pad 192 on the fourth region R₄′ of the second insulating layer 150. As a result of such an operation, the third electrode pad 191 may contact the plurality of third via electrodes 181 (exposed on the third region R₃′ of the second insulating layer 150), and the fourth electrode pad 192 may contact the plurality of fourth via electrodes 182 (exposed on the fourth region R₄′ of the second insulating layer 150).

Referring to FIG. 14, in the power semiconductor device, the first electrode pad 141 and the second electrode pad 142 may be on the plurality of first electrodes 111 and the plurality of second electrodes 112, respectively, and may be on the same plane of the first insulating layer 120, i.e., may have a side facing and sharing a plane with the first insulating layer 120, thereby constructing the first-layer electrode pad.

In addition, the third electrode pad 191 and the fourth electrode pad 192 may be on the first electrode pad 141 and the second electrode pad 142, respectively, and may be on the same plane of the second insulating layer 150, i.e., may have a side facing and sharing a plane with the second insulating layer 150, thereby constructing the second-layer electrode pad.

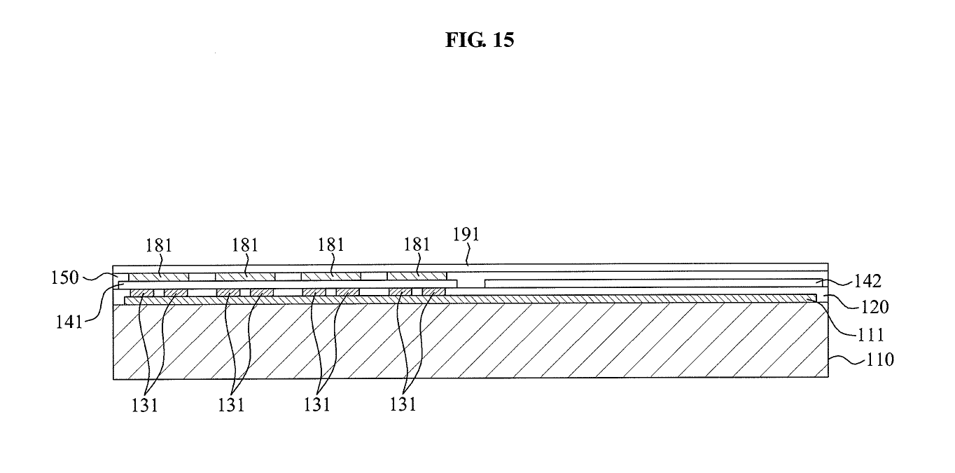

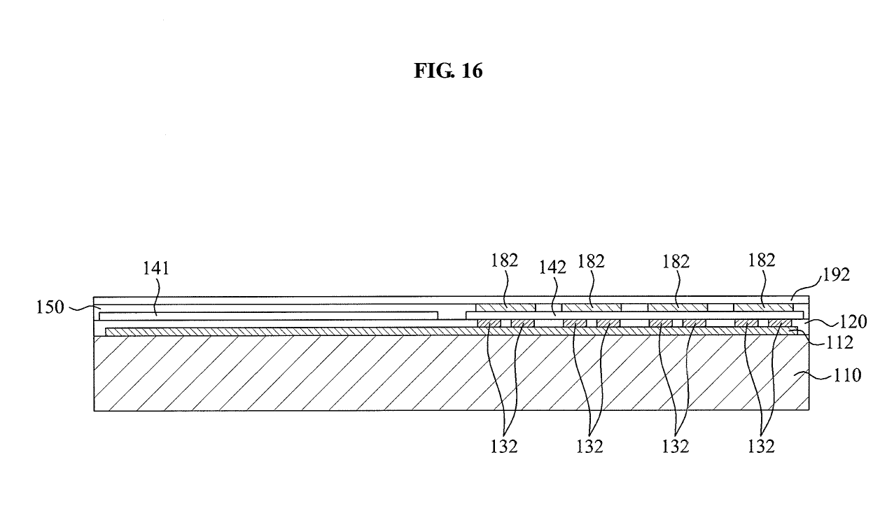

FIG. 15 illustrates a sectional view of the power semiconductor device shown in FIG. 14, taken along a line C-C′. FIG. 16 illustrates a sectional view of the power semiconductor device shown in FIG. 14, taken along a line D-D′. An electrode structure of the power semiconductor device will now be described in detail with reference to FIGS. 15 and 16.

FIG. 15 illustrates the third region R₃′ of the power semiconductor device shown in FIG. 14, taken along the line C-C′. An electrical connection structure of the plurality of first electrodes 111, the first electrode pad 141, and the third electrode pad 191 is shown in FIG. 15.

The plurality of first electrodes 111 may be on the epi structure 110. The first insulating layer 120 may be on the plurality of first electrodes 111. The first insulating layer 120 may be divided into the first region R₁ and the second region R₂, and may include or surround the plurality of first via electrodes 131 that contact the plurality of first electrodes 111 in the first region R₁.

The first electrode pad 141 may be disposed on the first region R₁ of the second insulating layer 120 and may contact the plurality of first via electrodes 131 exposed through the first insulating layer 120. For example, the plurality of first via electrodes 131 may function as a line for electrically connecting the plurality of first electrodes 111 with the first electrode pad 141.

The second electrode pad 142 may be on the second region R₂ of the first insulating layer 120. However, different from the case of the first electrode pad 141, the second region R₂ may not include the plurality of first via electrodes 131. Therefore, the second electrode pad 142 may be electrically insulated from the plurality of first electrodes 111 by the first insulating layer 120.

The second insulating layer 150 may be on the first electrode pad 141 and the second electrode pad 142. The second insulating layer 150 may include or surround a plurality of third via electrodes 181 in a part of the third region R₃′, e.g., the part overlapping the first region R_{I}. Accordingly, the plurality of third via electrodes 181 may contact the first electrode pad 141.

The third electrode pad 191 may be on the second insulating layer 150 and may contact the plurality of third via electrodes 181 that are exposed through the second insulating layer 150. The plurality of third via electrodes 181 may function as a line for electrically connecting the first electrode pad 141 with the third electrode pad 191.

FIG. 16 illustrates the fourth region R₄′ of the power semiconductor device shown in FIG. 14, taken along the line D-D′. An electrical connection structure of the plurality of second electrodes 112, the second electrode pad 142, and the fourth electrode pad 172 is shown in FIG. 16.

The plurality of second electrodes 112 is on the epi structure 110. The first insulating layer 120 may be on the plurality of second electrodes 112. The first insulating layer 120 may be divided into the first region R₁ and the second region R₂. The second region R₁ may include the plurality of second via electrodes 131 that contact the plurality of second electrodes 111.

The first electrode pad 141 may be on the first region R₁ of the first insulating layer 120 and may be electrically insulated from the plurality of second electrodes 112.

The second electrode pad 142 may contact the plurality of second via electrodes 132 that are exposed through the first insulating layer 120. For example, the plurality of second via electrodes 132 may function as a line for electrically connecting the plurality of second electrodes 112 with the second electrode pad 142.

The second insulating layer 150 may be on the first electrode pad 141 and the second electrode pad 142. The second insulating layer 150 may include or surround the plurality of fourth via electrodes 182 in a part of the fourth region R₄′, e.g., the part overlapping the second region R₂. Accordingly, the plurality of fourth via electrodes 182 may contact the second electrode pad 142.

The fourth electrode pad 192 may be on the second insulating layer 150 and may contact the plurality of fourth via electrodes 182 that are exposed through the second insulating layer 150. The plurality of fourth via electrodes 182 may function as a line for electrically connecting the second electrode pad 142 with the fourth electrode pad 192.

In FIGS. 15 and 16, the first electrode pad 141 and the second electrode pad 142 may be on the same plane, thereby constructing the first-layer electrode pad. The third electrode pad 191 and the fourth electrode pad 192 may be on the same plane, thereby constructing the second-layer electrode pad.

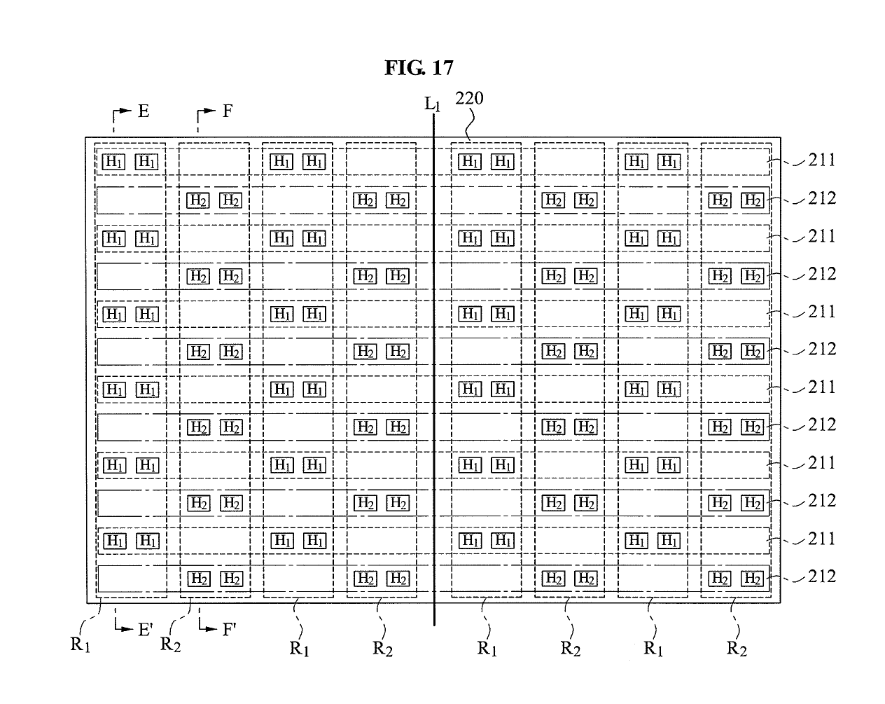

FIGS. 17 through 37 illustrate diagrams of stages in a manufacturing method of a power semiconductor device according to an embodiment.

First, a plurality of first electrodes 211 and a plurality of second electrodes 212 may be formed on an epi structure 210 according to the same process as illustrated in FIGS. 1 and 2. Then, a first insulating layer 220 may be formed to cover the plurality of first electrodes 211 and the plurality of second electrodes 212.

FIGS. 17 to 19 illustrate stages in a process of forming a plurality of first via holes H₁ and a plurality of second via holes H₂ on the first insulating layer 220.

Referring to FIG. 17, the manufacturing method may include forming the plurality of first via holes H₁ and the plurality of second via holes H₂ on or in the first insulating layer 220.

The first insulating layer 220 may be divided into first regions R₁ and second regions R₂ arranged to alternate with each other, e.g., four times. For example, four first regions R₁ and four second regions R₂ may be alternately arranged in the first insulating layer 220. The first regions R₁ are regions to form a first electrode pad while the second regions R₂ are regions to form a second electrode pad. The first regions R₁ and the second regions R₂ may be defined in a direction across from the plurality of first electrodes 211 and the plurality of second electrodes 212, on the first insulating layer 220.

The plurality of first via holes H₁ is formed in the first regions R₁ of the first insulating layer 220 such that at least a portion of the plurality of first electrodes 211 is exposed. The plurality of second via holes H₂ is formed in the second regions R₂ of the first insulating layer 220 such that at least a portion of the plurality of second electrodes 212 is exposed. The plurality of first via holes H₁ and the plurality of second via holes H₂ may have a first size.

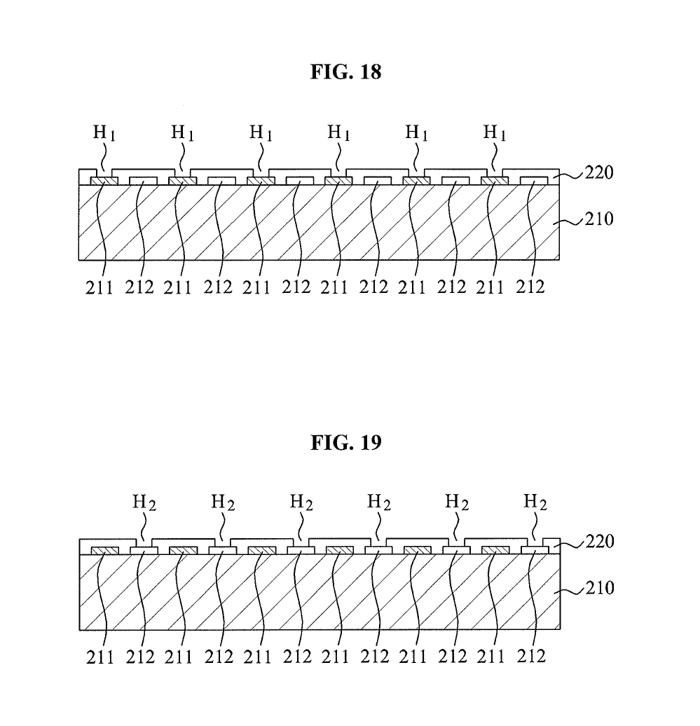

FIG. 18 illustrates a sectional view of one of the first regions R₁ of the power semiconductor device shown in FIG. 17, taken along a line E-E′.

The plurality of first electrodes 211 and the plurality of second electrodes 212 may be alternately arranged on the epi structure 210. The first insulating layer 220 may be disposed on the plurality of first electrodes 211 and the plurality of second electrodes 212 and may include the plurality of first via holes H₁ therethrough. The plurality of first via holes H₁ may expose at least a portion of the plurality of first electrodes 211 in the first regions R₁.

FIG. 19 illustrates a sectional view of one of the second regions R₂ of the power semiconductor device shown in FIG. 17, taken along a line F-F′.

The plurality of first electrodes 211 and the plurality of second electrodes 212 may be alternately arranged on the epi structure 210. The first insulating layer 220 may be on the plurality of first electrodes 211 and the plurality of second electrodes 212 and may include the plurality of second via holes H₂ therethrough. The plurality of second via holes H₂ may expose at least a portion of the plurality of second electrodes 212 in the second regions R₂.

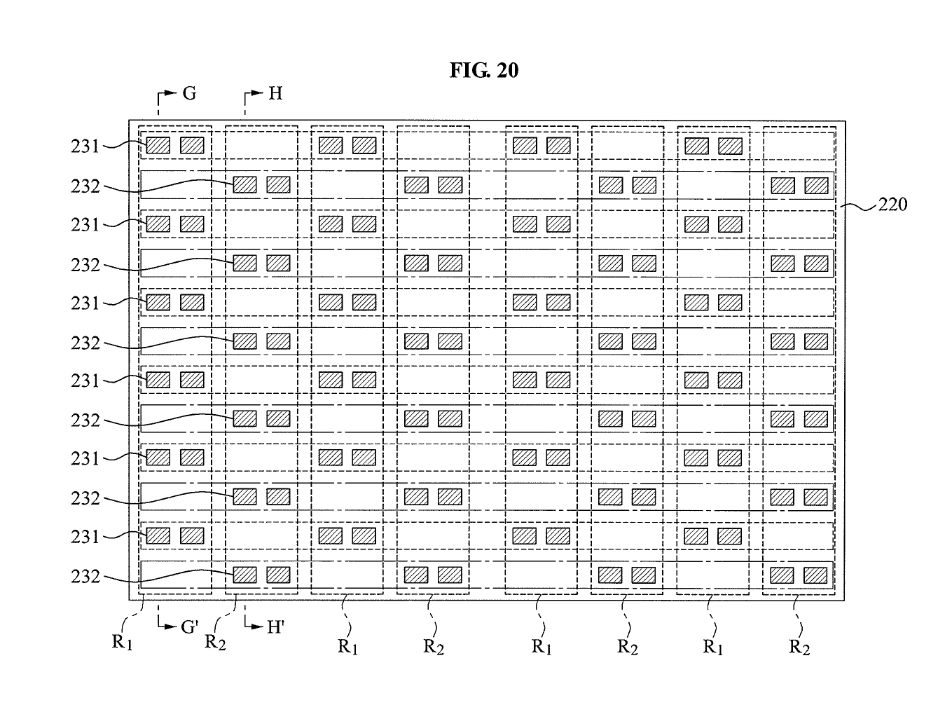

FIGS. 20 to 22 illustrate stages in a process of forming a plurality of via electrodes 231 and a plurality of via electrodes 232.

Referring to FIG. 20, the manufacturing method may include forming the plurality of first via electrodes 231 by casting a metallic material in the plurality of first via holes H₁, and forming a plurality of second via electrodes 232 by casting a metallic material in the plurality of second via holes H₂. For example, the plurality of first via electrodes 231 may be formed in the first regions R₁ of the first insulating layer 220 and may contact the plurality of first electrodes 211. The plurality of second via electrodes 232 may be formed in the second regions R₂ of the first insulating layer 220 and may contact the plurality of second electrodes 212.

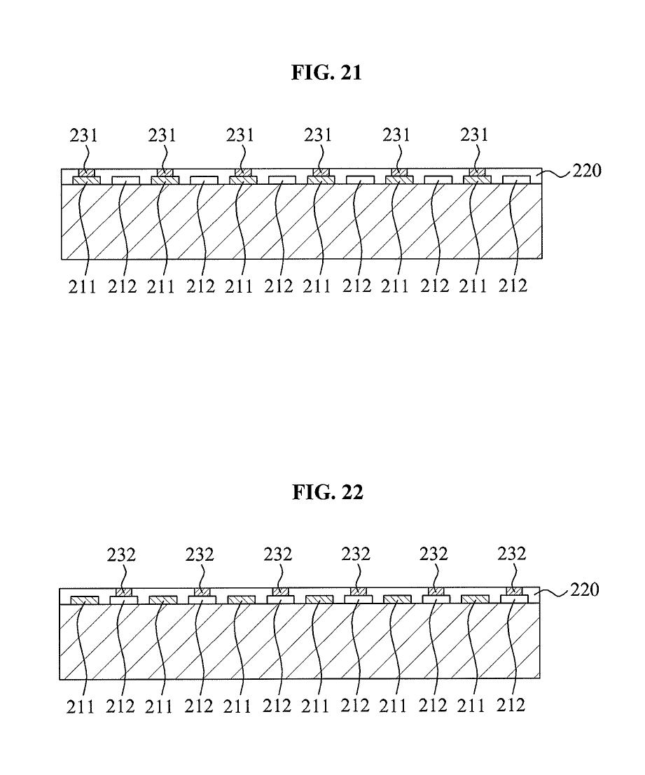

FIG. 21 illustrates a sectional view of one of the first regions R₁ of the power semiconductor device shown in FIG. 20, taken along a line G-G′.

The first insulating layer 220 may include or surround the plurality of first via electrodes 231 disposed in the first regions R₁. The plurality of first via electrodes 231 may contact the plurality of first electrodes 211 in the first regions R₁.

FIG. 22 illustrates a sectional view of one of the second regions R₂ of the power semiconductor device shown in FIG. 20, taken along a line H-H′.

The first insulating layer 220 may include or surround the plurality of second via electrodes 232 in the second regions R₂. The plurality of second via electrodes 232 may contact the plurality of second electrodes 212 in the second regions R₂.

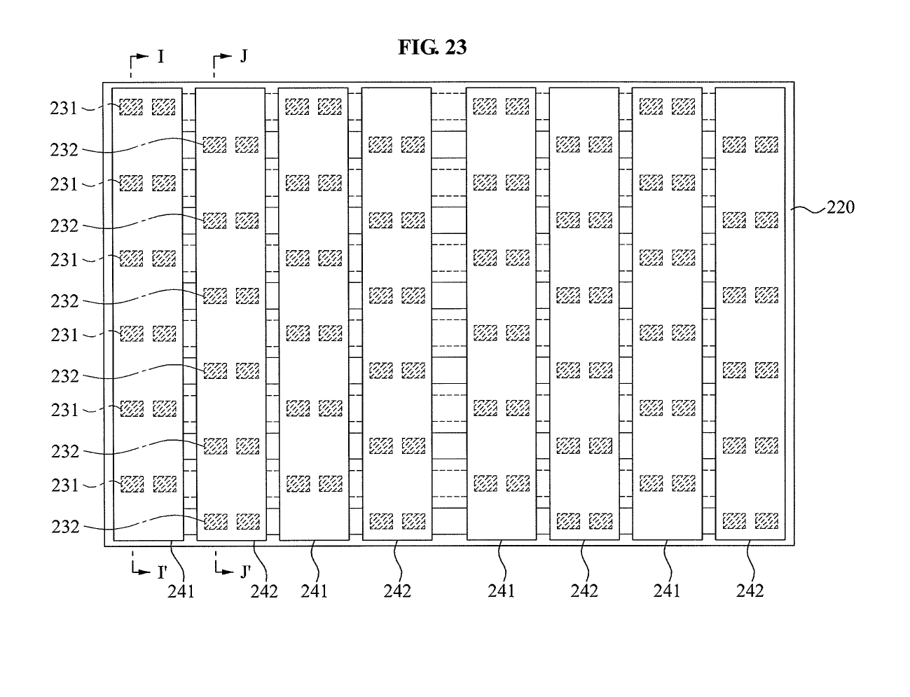

FIGS. 23 to 25 illustrate stages in a process of forming a first electrode pad 241 and a second electrode pad 242.

Referring to FIG. 23, the manufacturing method may include forming the first electrode pad 241 on the first regions R₁ of the first insulating layer 220 and forming the second electrode pad 242 on the second regions R₂ of the first insulating layer 220. As a result of such an operation, the first electrode pad 241 may contact the plurality of first via electrodes 231 that are exposed on the first regions R₁, and the second electrode pad 242 may contact the plurality of second via electrodes 232 that are exposed on the second regions R₂.

The first electrode pad 241 and the second electrode pad 242 may be on the first regions R₁ and the second regions R₂ (alternating four times on the first insulating layer 220). For example, the first electrode pad 241 and the second electrode pad 242 may alternate corresponding to positions of the first regions R₁ and the second regions R₂.

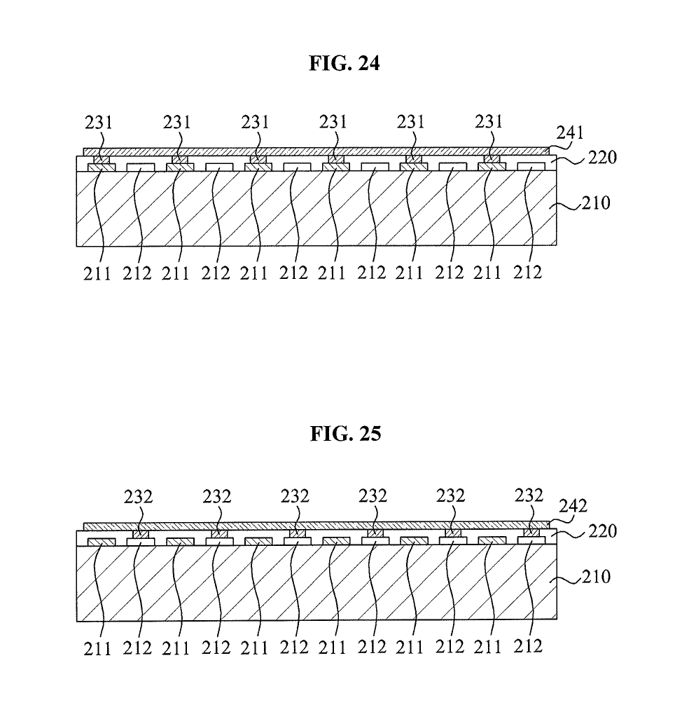

FIG. 24 illustrates a sectional view of one of the first regions R₁ of the power semiconductor device shown in FIG. 23, taken along a line I-I′.

The first electrode pad 241 may be formed on the first regions R₁ of the first insulating layer 220 and may contact the plurality of first via electrodes 231 that are exposed through the first insulating layer 220. The plurality of first via electrodes 231 may function as a line for electrically connecting the plurality of first electrodes 211 with the first electrode pad 241.

FIG. 25 illustrates a sectional view of one of the second regions R₂ of the power semiconductor device shown in FIG. 23, taken along a line J-J′.

The second electrode pad 242 may be formed on the second regions R₂ of the first insulating layer 220 and may contact the plurality of second via electrodes 232. The plurality of second via electrodes 232 may function as a line for electrically connecting the plurality of second electrodes 212 with the second electrode pad 242.

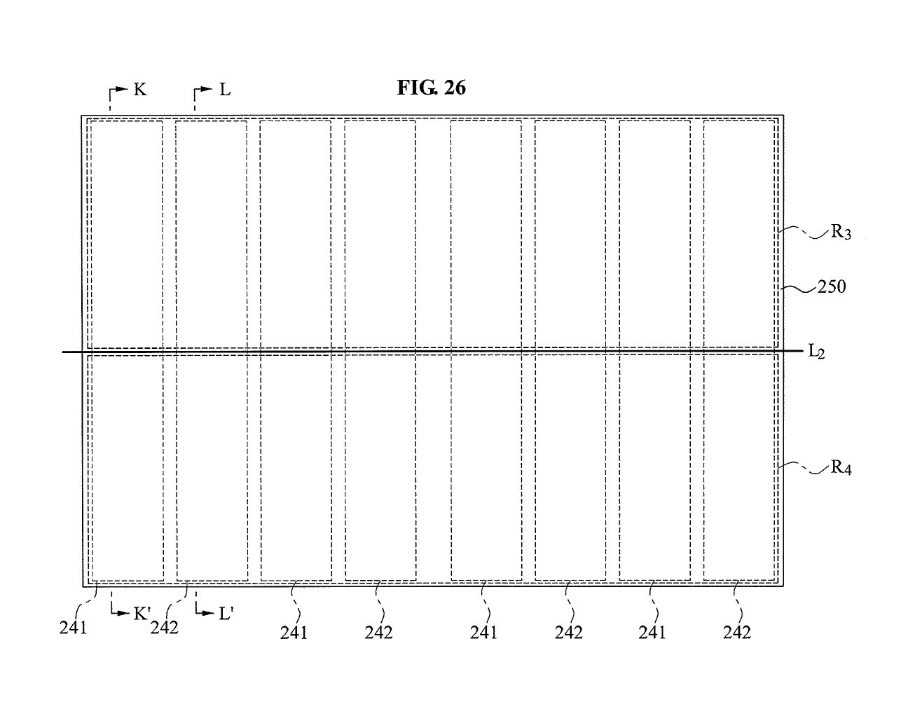

FIGS. 26 to 28 illustrate stages in a process of forming a second insulating layer 250.

Referring to FIG. 26, the manufacturing method may include forming the second insulating layer 250 by, e.g., vapor-depositing an insulating material to cover the first electrode pad 241 and the second electrode pad 242. In addition, after the second insulating layer 250 is formed, an upper portion of the second insulating layer 250 may be divided into a third region R₃ and a fourth region R₄.

The third region R₃ and the fourth region R₄ may be arranged symmetrically to each other with respect to a second straight line L₂ that passes through a center of the epi structure 210 and is orthogonal to the first straight line L_{I}. The third region R₃ may be a region in which a third electrode pad is to be formed. The fourth region R₄ is a region in which a fourth electrode pad is to be formed.

In FIG. 26, the third region R₃ may cross the first regions R₁ and the second regions R₂ while only partially overlapping the first regions R₁ and the second regions R₂. The fourth region R₄ may cross the first regions R₁ and the second regions R₂ while only partially overlapping the first regions R₁ and the second regions R₂. In addition, the third region R₃ and the fourth region R₄ may be defined in a direction across from the first electrode pad 241 and the second electrode pad 242 on the second insulating layer 250.

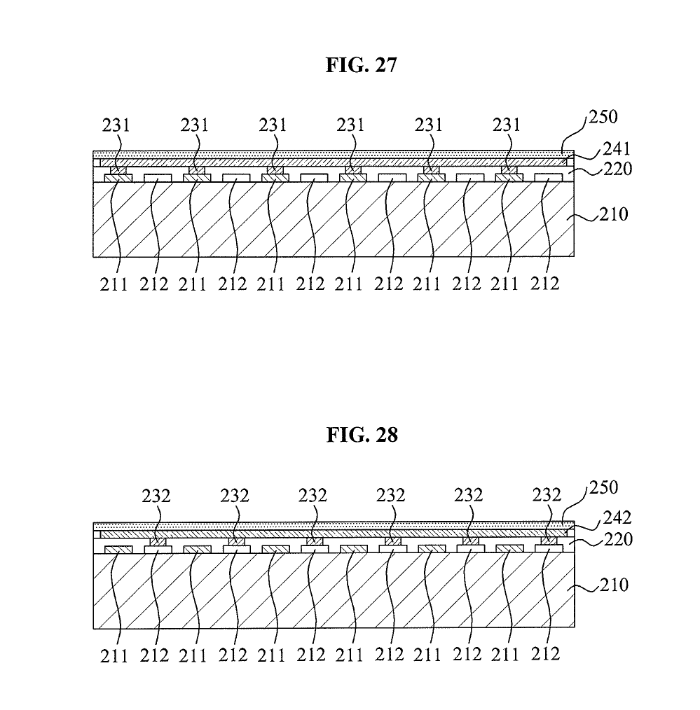

FIG. 27 illustrates a sectional view of one of the first region R₁ of the power semiconductor device shown in FIG. 26, taken along a line K-K′. FIG. 28 illustrates a sectional view of one of the second regions R₂ of the power semiconductor device shown in FIG. 26, taken along a line L-L′.

The second insulating layer 250 may be disposed on the first electrode pad 241 and the second electrode pad 242 to fully cover the first electrode pad 241 and the second electrode pad 242.

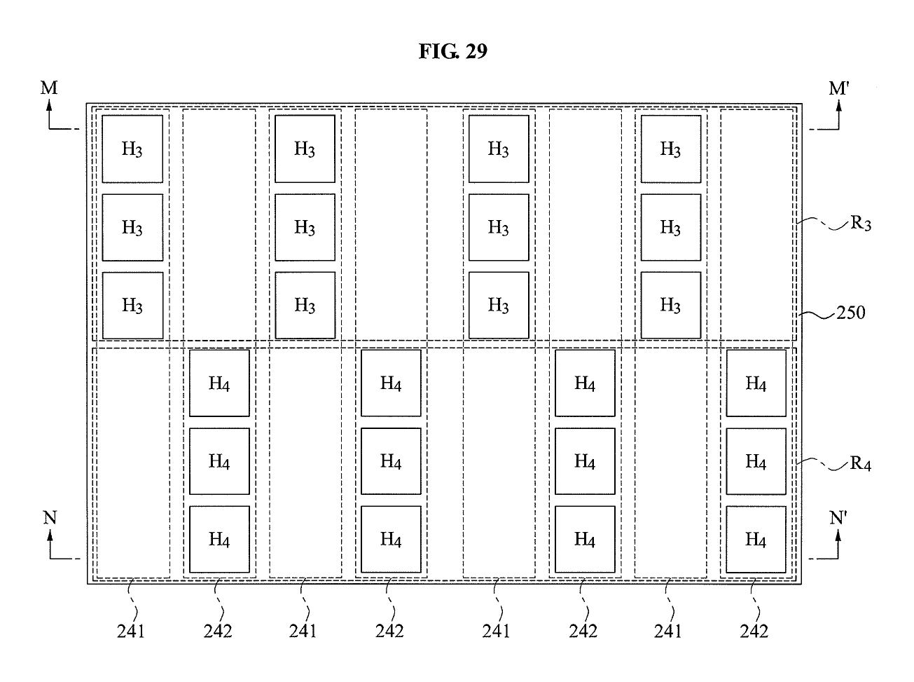

FIGS. 29 to 31 illustrate stages in a process of forming a plurality of third via holes H₃ and a plurality of fourth via holes H₄.

Referring to FIG. 29, the manufacturing method may include forming the plurality of third via holes H₃ and the plurality of fourth via holes H₄ on or in the second insulating layer 250. For example, the plurality of third via holes H₃ may be formed in the third region R₃ of the second insulating layer 250 such that at least a portion of the first electrode pad 241 is exposed. Also, the plurality of fourth via holes H₄ may be formed in the fourth region R₄ of the second insulating layer 250 such that at least a portion of the second electrode pad 242 is exposed.

The plurality of third via holes H₃ and the plurality of fourth via holes H₄ may have a second size that is larger than the first size of the plurality of first via holes H₁ an the plurality of second via holes H₂.

In an implementation, the plurality of third via holes H₃ may have a second size that is larger than the first size of the plurality of first via holes H₁ and the plurality of second via holes H₂, and the plurality of fourth via holes H₄ may have a third size. In this case, the third size may be larger than the first size, and greater or smaller than, i.e., different from, the second size.

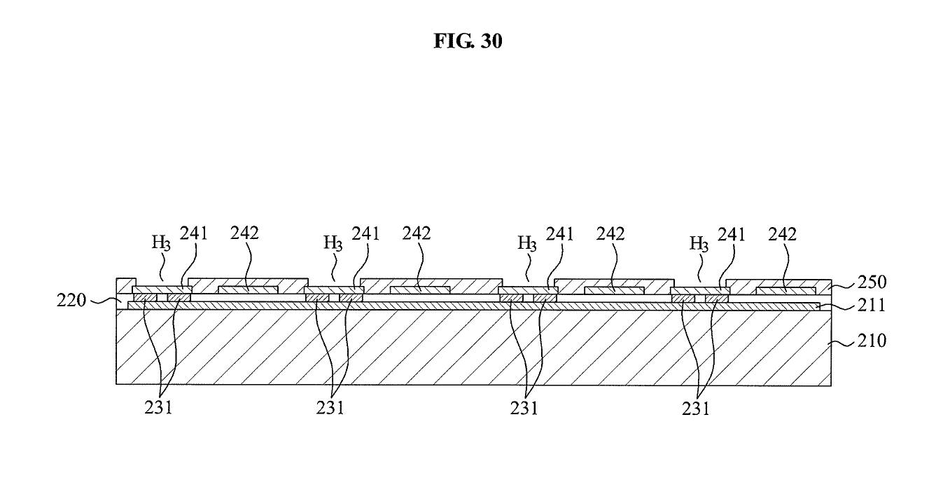

FIG. 30 illustrates a sectional view of the third region R₃ of the power semiconductor device shown in FIG. 29, taken along a line M-M′.

In the third region R₃ of the second insulating layer 250, at least a portion of the first electrode pad 241 may be exposed through the plurality of third via holes H₃. However, in the third region R₃, the second electrode pad 242 may be insulated from the outside by being covered with the second insulating layer 250.

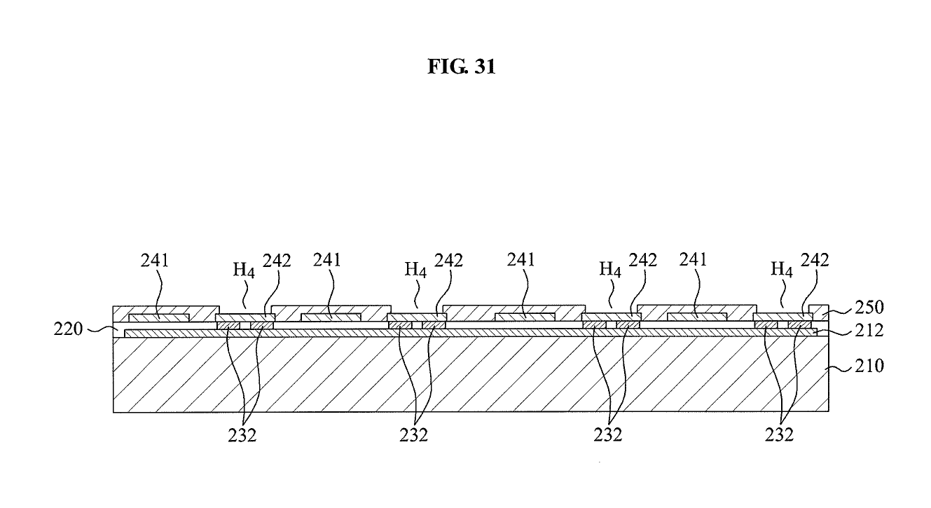

FIG. 31 illustrates a sectional view of the fourth region R₄ of the power semiconductor device shown in FIG. 29, taken along a line N-N′.

In the fourth region R₄ of the second insulating layer 250, at least a portion of the second electrode pad 242 may be exposed through the plurality of fourth via holes H₄. However, in the fourth region R₄, the first electrode pad 241 may be insulated from the outside by being covered with the second insulating layer 250.

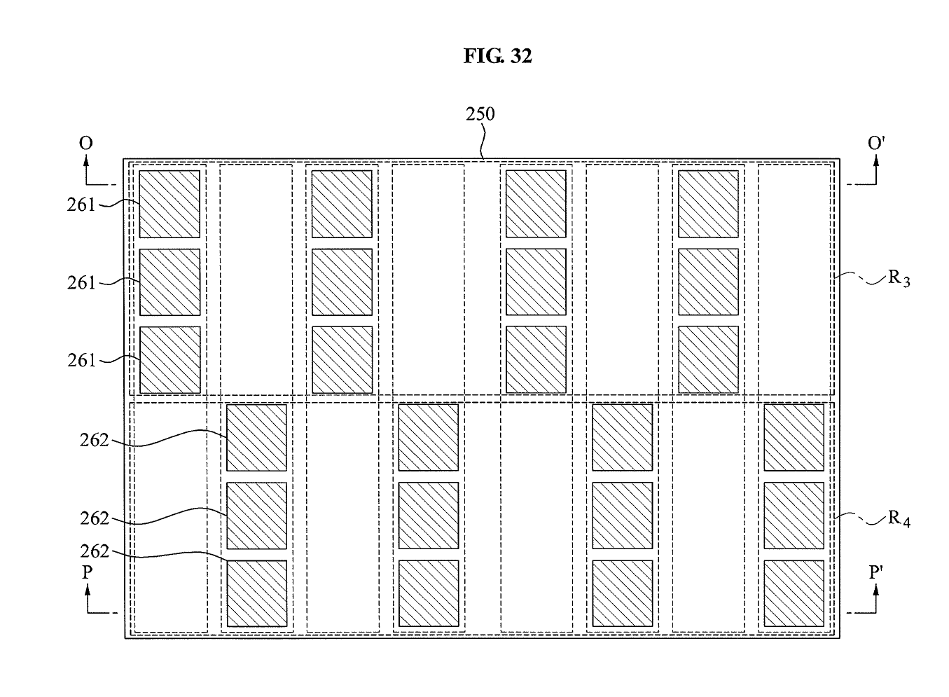

FIGS. 32 to 34 illustrate stages in a process of forming a plurality of third via electrodes 261 and a plurality of fourth via electrodes 262.

Referring to FIG. 32, the manufacturing method may include forming the plurality of third via electrodes 261 by casting a metallic material in the plurality of third via holes H₃, and forming the plurality of fourth via electrodes 262 by casting a metallic material in the plurality of fourth via holes H₄. For example, the plurality of third via electrodes 261 may be formed in the third region R₃ of the second insulating layer 250 and may contact the first electrode pad 241. The plurality of fourth via electrodes 262 may be formed in the fourth region R₄ of the second insulating layer 250 and may contact the second electrode pad 242.

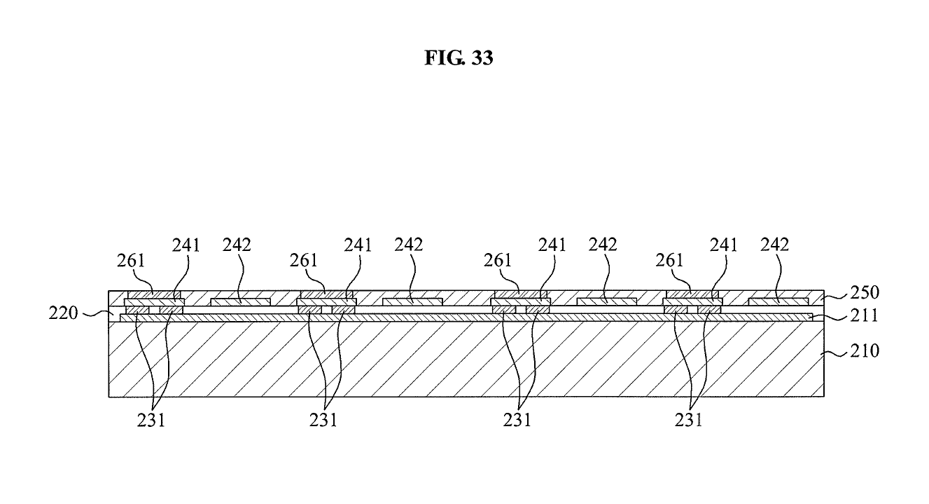

FIG. 33 illustrates a sectional view of the third region R₃ of the power semiconductor device shown in FIG. 32, taken along a line O-O′.

The plurality of third via electrodes 261 may be formed in the third region R₃ of the second insulating layer 250 and may contact the first electrode pad 241. Also, the plurality of third via electrodes 261 may be exposed through the second insulating layer 250.

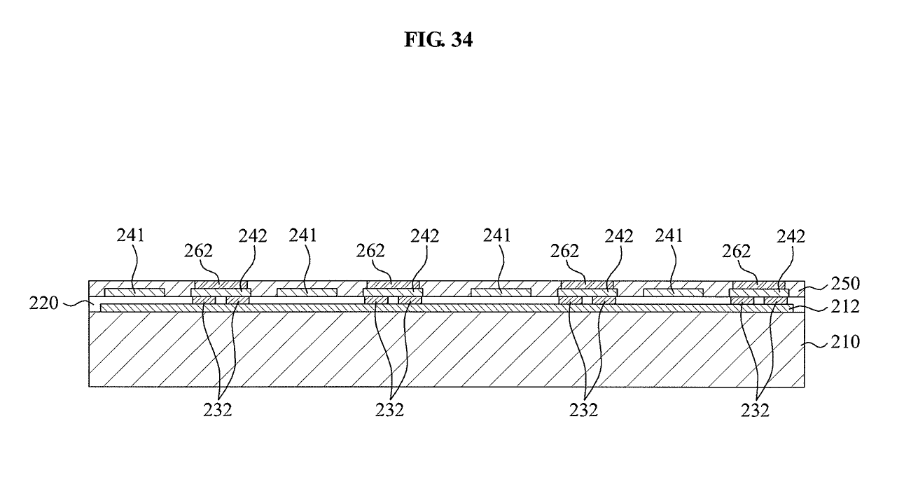

FIG. 34 illustrates a sectional view of the fourth region R₄ of the power semiconductor device shown in FIG. 32, taken along a line P-P′.

The plurality of fourth via electrodes 262 may be formed in the fourth region R₄ of the second insulating layer 250 and may contact the second electrode pad 242. Also, the plurality of fourth via electrodes 262 may be exposed through the second insulating layer 250.

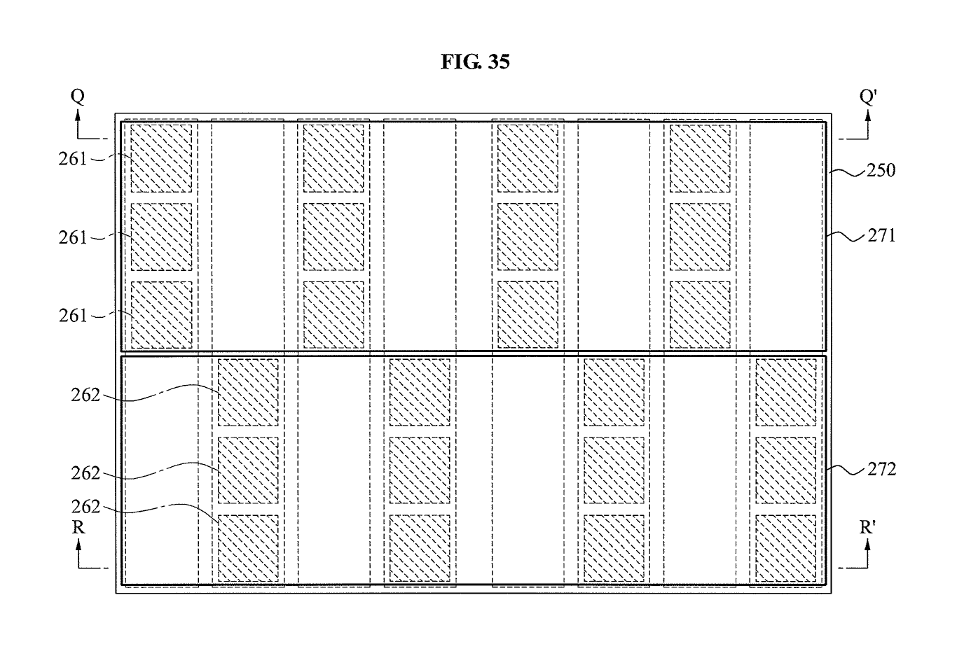

FIGS. 35 to 37 illustrate stages in a process of forming a third electrode pad 271 and a fourth electrode pad 272.

Referring to FIG. 35, the manufacturing method may include forming the third electrode pad 271 on the third region R₃ of the second insulating layer 250, and forming the fourth electrode pad 272 on the fourth region R₄ of the second insulating layer 250. As a result of such an operation, the third electrode pad 271 may contact the plurality of third via electrodes 261 that are exposed on the third region R₃ of the second insulating layer 250, and the fourth electrode pad 272 may contact the plurality of fourth via electrodes 262 that are exposed on the fourth region R₄ of the second insulating layer 250.

The plurality of third via electrodes 261 may function as a line for electrically connecting the first electrode pad 241 with the third electrode pad 271. The plurality of fourth via electrodes 262 may function as a line for electrically connecting the second electrode pad 242 with the fourth electrode pad 271.

Referring to FIG. 35, the power semiconductor device may have a multilayer electrode structure. For example, the first electrode pad 241 and the second electrode 242 may be on the plurality of first electrodes 211 and the plurality of second electrodes 212, respectively, and may be on the same plane of the first insulating layer 220, i.e., may have a side that faces and shares a plane with the first insulating layer 220, thereby constructing a first-layer electrode pad.

In addition, the third electrode pad 271 and the fourth electrode pad 272 may be on the first electrode pad 241 and the second electrode pad 242, respectively, and may be on the same plane of the second insulating layer 250, i.e., may have a side that faces and share a plane with the second insulating layer 250, thereby constructing a second-layer electrode pad.

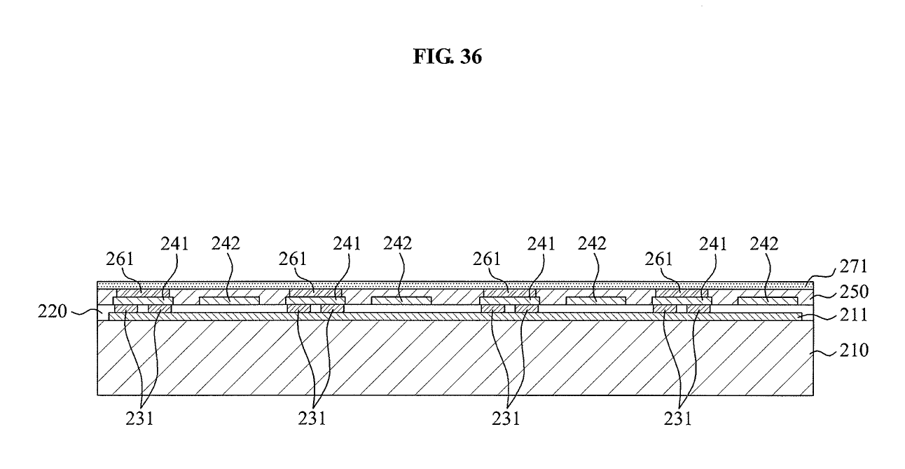

FIG. 36 illustrates a sectional view of the third region R₃ of the power semiconductor device shown in FIG. 35, taken along a line Q-Q′.

The third electrode pad 271 may be formed on the second insulating layer 250 and may contact the plurality of third via electrodes 261 that are exposed through the second insulating layer 250. The plurality of third via electrodes 261 may function as a line for electrically connecting the first electrode pad 241 with the third electrode pad 271.

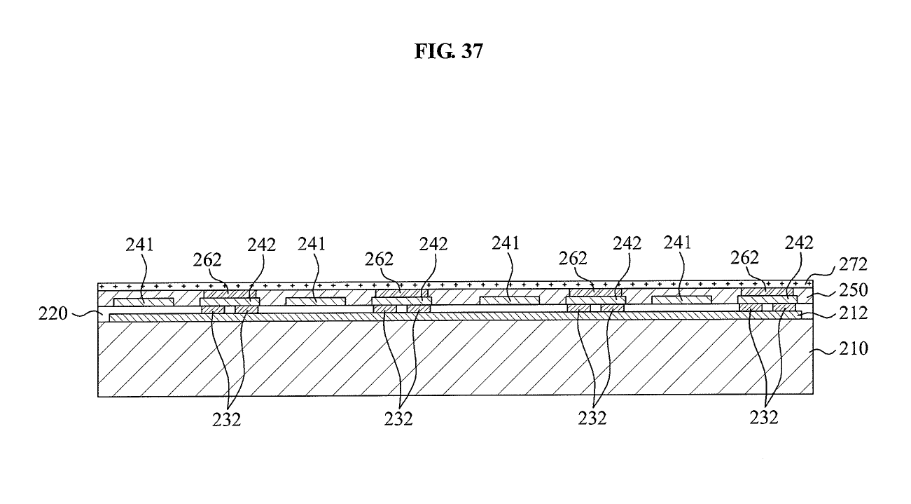

FIG. 37 illustrates a sectional view of the fourth region R₄ of the power semiconductor device shown in FIG. 35, taken along a line R-R′.

The fourth electrode pad 272 may be formed on the second insulating layer 250 and may contact the plurality of fourth via electrodes 262 that are exposed through the second insulating layer 250. The plurality of fourth via electrodes 262 may function as a line for electrically connecting the second electrode pad 242 with the fourth electrode pad 272.

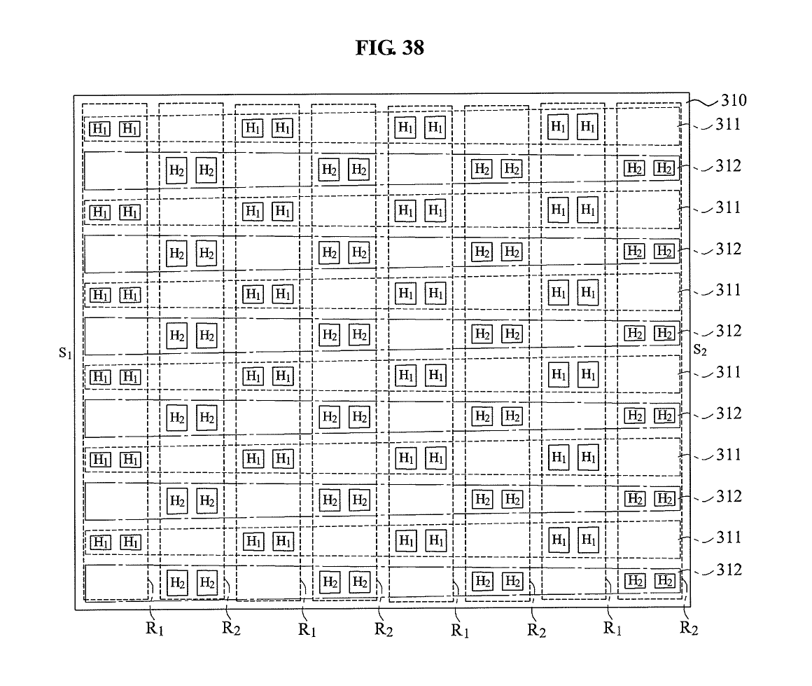

FIG. 38 illustrates a plan view of a power semiconductor device according to an embodiment. Referring to FIG. 38, the power semiconductor device may include a plurality of first electrodes 311 and a plurality of second electrodes 312 that are provided with or have a tapered structure. In addition, the power semiconductor device may further include a first insulating layer 310 on the plurality of first electrodes 311 and the plurality of second electrodes 312, and a plurality of first via holes H₁ and a plurality of second via holes H₂ may be included in the first insulating layer 310.

The plurality of first electrodes 311 may each have a tapered structure having an increasing width in a direction from one side S₁ to an opposite side S₂ of the first insulating layer 310. The plurality of second electrodes 312 may each have a tapered structure having an increasing width in a direction from the opposite side S₂ to the one side S₁.

The first insulating layer 310 may be disposed on an epi structure to cover the plurality of first electrodes 311 and the plurality of second electrodes 312. The first insulating layer 310 may be divided into a first region R₁ and a second region R₂ that alternate at least once.

The plurality of first via holes H₁ may be formed in the first region R₁ of the first insulating layer 310 to expose at least a portion of the plurality of first electrodes 311. The plurality of second via holes H₂ may be formed in the second region R₂ of the first insulating layer 310 to expose at least a portion of the plurality of second electrodes 312.

The plurality of first via holes H₁ may be provided in or have a trapezoidal shape that widen toward the opposite side S₂ in the first region R₁, e.g., corresponding to the tapered structure or shape of the plurality of first electrodes 311.

The plurality of second via holes H₂ may be provided in or have a trapezoidal shape widening toward the one side S₁ in the second region R₂, e.g., corresponding to the tapered structure of the plurality of second electrodes 312.

Accordingly, when a plurality of first via electrodes and a plurality of second via electrodes are formed by casting a metallic material in the plurality of first via holes H₁ and the plurality of second via holes H₂, the plurality of first via electrodes and the plurality of second via electrodes may also be provided in or have a trapezoidal shape.

Although not specifically shown in the drawings, the power semiconductor device shown in FIG. 38 may be manufactured using the method illustrated in FIGS. 20 through 37.

By way of summation and review, electronic devices including the GaN-based material may have a high breakdown voltage, high maximum current density, and high operational stability and heat conductivity at a high temperature. For example, electronic devices having a hetero junction structure of aluminum gallium nitride (AlGaN) and GaN may have high band discontinuity at a junction interface. Thus, such an electronic device may free high density electrons and increase electron mobility.

Due to the aforementioned physical properties, the electronic device including the GaN-based material may be employed as a power semiconductor device. For this purpose, the power semiconductor device may need to maintain a high withstand voltage without reaching the breakdown voltage, even under a high voltage. However, it may be difficult for the power semiconductor device including the GaN-based material to endure withstand voltage due to bulk defects, surface defects, and the like.

The embodiments provide a power semiconductor device having a multilayer electrode pad to realize an isoelectric and equicurrent state, and a high withstand voltage.

The embodiments provide a power semiconductor device capable of realizing an equipotential and equicurrent state by providing a multilayer electrode pad on a plurality of first electrodes and a plurality of second electrodes disposed on an epi structure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A power semiconductor device, comprising:
a plurality of first electrodes and a plurality of second electrodes alternately arranged on an epi structure;
a first insulating layer on the epi structure, the first insulating layer including at least one first region alternately arranged with at least one second region;
a plurality of first via electrodes on the first region of the first insulating layer, the plurality of first via electrodes contacting the plurality of first electrodes;
a plurality of second via electrodes on the second region of the first insulating layer, the plurality of second via electrodes contacting the plurality of second electrodes;
at least one first electrode pad on the first region, the at least one first electrode pad contacting the plurality of first via electrodes;
at least one second electrode pad on the second region, the at least one second electrode pad contacting the plurality of second via electrodes;
a second insulating layer on the at least one first electrode pad and the at least one second electrode pad, the second insulating layer including a third region and a fourth region;
a plurality of third via electrodes on the third region of the second insulating layer, the plurality of third via electrodes contacting the at least one first electrode pad;
a plurality of fourth via electrodes on the fourth region of the second insulating layer, the plurality of fourth via electrodes contacting the at least one second electrode pad;
at least one third electrode pad on the third region, the at least one third electrode pad contacting the plurality of third via electrodes; and
at least one fourth electrode pad disposed on the fourth region, the at least one third electrode pad contacting the plurality of fourth via electrodes.

2. The power semiconductor device as claimed in claim 1, wherein:
the plurality of first via electrodes and the plurality of second via electrodes each have a first size, and
the plurality of third via electrodes and the plurality of fourth via electrodes each have a second size, the second size larger than the first size.

3. The power semiconductor device as claimed in claim 1, wherein:
the plurality of first via electrodes and the plurality of second via electrodes each have a first size,
the plurality of third via electrodes each have a second size, the second size being larger than the first size, and
the plurality of fourth via electrodes each have a third size, the third size being larger than the first size and being different from the second size.

4. The power semiconductor device as claimed in claim 1, wherein the plurality of first electrodes each have a tapered structure that widens from one side to an opposite side of the epi structure.

5. The power semiconductor device as claimed in claim 4, wherein the plurality of second electrodes each have a tapered structure that widens from the opposite side to the one side of the epi structure.

6. The power semiconductor device as claimed in claim 5, wherein the plurality of second via electrodes each have a trapezoidal shape that widens toward the opposite side within the second region and corresponds to the tapered structure of the plurality of second electrodes.

7. The power semiconductor device as claimed in claim 4, wherein the plurality of first via electrodes each have a trapezoidal shape that widens toward the opposite side within the first region and corresponds to the tapered structure of the plurality of first electrodes.

8. The power semiconductor device as claimed in claim 1, wherein the first region and the second region are arranged symmetrically to each other with respect to a first straight line passing through a center of the epi structure.

9. The power semiconductor device as claimed in claim 8, wherein the third region and the fourth region are arranged symmetrically to each other with respect to a second straight line passing through the center of the epi structure, the second straight line being orthogonal to the first straight line.

10. The power semiconductor device as claimed in claim 1, wherein the first region and the second region each have a major axis that extends in a direction crossing a major axis of the plurality of first electrodes and the plurality of second electrodes in the first insulating layer.

11. The power semiconductor device as claimed in claim 10, wherein the third region and the fourth region each have a major axis that extends in a direction crossing a major axis of the at least one first electrode pad and the at least one second electrode pad in the second insulating layer.

12. A manufacturing method for a power semiconductor device, the method comprising:
forming a plurality of first electrodes and a plurality of second electrodes such that the plurality of first electrodes and the plurality of second electrodes are alternately arranged on an epi structure;
forming a first insulating layer on the epi structure such that the first insulating layer includes at least one first region alternately arranged with at least one second region;
forming a plurality of first via holes in the first region of the first insulating layer such that the plurality of first electrodes are exposed;
forming a plurality of second via holes in the second region of the first insulating layer such that the plurality of second electrodes are exposed;
forming a plurality of first via electrodes by casting a metallic material in the plurality of first via holes;
forming a plurality of second via electrodes by casting a metallic material in the plurality of second via holes;
forming at least one first electrode pad in contact with the plurality of first via electrodes on the first region;
forming at least one second electrode pad in contact with the plurality of second via electrodes disposed on the second region;
forming a second insulating layer on the at least one first electrode pad and the at least one second electrode pad, the second insulating layer including a third region and a fourth region;
forming a plurality of third via holes in a third region of the second insulating layer such that the at least one first electrode pad is exposed;
forming a plurality of fourth via holes in a fourth region of the second insulating layer such that the at least one second electrode pad is exposed;
forming a plurality of third via electrodes by casting a metallic material in the plurality of third via holes;
forming a plurality of fourth via electrodes by casting a metallic material in the plurality of fourth via holes;
forming at least one third electrode pad in contact with the plurality of third via electrodes on the third region; and
forming at least one fourth electrode pad in contact with the plurality of fourth via electrodes on the fourth region.

13. The manufacturing method as claimed in claim 12, wherein:
forming the plurality of first via holes and the plurality of second via holes includes forming the plurality of first via holes and the plurality of second via holes to each have a first size, and
forming the plurality of third via holes and the plurality of fourth via holes includes forming the plurality of third via holes and the plurality of fourth via holes to each have a second size that is larger than the first size.

14. The manufacturing method as claimed in claim 12, wherein:
forming the plurality of first via holes and the plurality of second via holes includes forming the plurality of first via holes and the plurality of second via holes to each have a first size,
forming the plurality of third via holes and the plurality of fourth via holes includes:
forming the plurality of third via holes to each have a second size that is larger than the first size, and
forming the plurality of fourth via holes to have a third size that is larger than the first size and that is different from the second size.

15. The manufacturing method as claimed in claim 12, wherein forming the plurality of first electrodes and the plurality of second electrodes includes:
forming the plurality of first electrodes such that each of the first electrodes has a tapered structure that widens from one side to an opposite side of the epi structure, and
forming the plurality of second electrodes such that each of the second electrodes has a tapered structure that widens from the opposite side to the one side of the epi structure.

16. The manufacturing method as claimed in claim 15, wherein forming the plurality of first via holes and the plurality of second via holes includes:
forming the plurality of first via holes such that each of the first via holes has a trapezoidal shape that widens in a direction from the opposite side of the epi structure to the one side of the epi structure and that corresponds to the tapered structure of the plurality of first electrodes, and
forming the plurality of second via holes such that each of the second via holes has a trapezoidal shape that widens in a direction from the one side of the epi structure to the opposite side of the epi structure and that corresponds to the tapered structure of the plurality of second electrodes.

17. The manufacturing method as claimed in claim 12, wherein the first region and the second region are arranged symmetrically to each other with respect to a first straight line passing through a center of the epi structure.

18. The manufacturing method as claimed in claim 17, wherein the third region and the fourth region are arranged symmetrical to each other with respect to a second straight line passing through the center of the epi structure, the second straight line being orthogonal to the first straight line.

19. The manufacturing method as claimed in claim 12, wherein the first region and the second region each have a major axis that extends in a direction crossing a major axis of the plurality of first electrodes and the plurality of second electrodes in the first insulating layer.

20. The manufacturing method as claimed in claim 12, wherein the third region and the fourth region each have a major axis that extends in a direction crossing a major axis of the at least one first electrode pad and the at least one second electrode pad in the second insulating layer.
